(19) United States
(12) Patent Application Publication
(10) Pub. No.: US 2023/0213684 A1
(43) Pub. Date: Jul. 6, 2023

(54) METHOD AND SYSTEM FOR INVERTED DETECTION AND POSITIONING OF STRIP-LIKE SUBTERRANEAN TUNNEL IN MOUNTAIN MASS

(71) Applicant: HUAZHONG UNIVERSITY OF SCIENCE AND TECHNOLOGY, Wuhan (CN)

(72) Inventors: Tianxu Zhang, Wuhan (CN); Yongjun JIA, Wuhan (CN); Chunlong WANG, Wuhan (CN); Yuehuan WANG, Wuhan (CN); Xiuchang GU, Wuhan (CN); Kechao WANG, Wuhan (CN); Wenbing DENG, Wuhan (CN); Xin LIU, Wuhan (CN)

(21) Appl. No.: 18/148,476

(22) Filed: Dec. 30, 2022

(30) Foreign Application Priority Data
Dec. 31, 2021 (CN) 2021116766025

(51) Int. Cl. G01V 8/02; G01V 99/00; G06F 30/13

(52) U.S. Cl. CPC G01V 8/02; G01V 99/005; G06F 30/13

(57) ABSTRACT

Methods and systems are provided for inverted detection and positioning of a strip-like subterranean tunnel in a mountain mass, pertaining to the field combining theories of the discipline of geophysics and remote sensing technology. The method includes: using a model of thermal radiation between a mountain mass and an air layer in conjunction with DEM data to calculate solar radiation energy, and iteratively filtering out background heat flow field energy of the mountain mass; calculating mountain mass background heat propagation energy with reference to hyperspectral data; using a subterranean target inversion model to filter out each layer of background heat flow field energy of the mountain mass in an infrared remote sensing image, and acquiring an optimal elevation of the strip-like subterranean tunnel in the mountain mass and a disturbance signal distribution image constructed via strip-like subterranean tunnel heat flow field energy in each layer of the mountain mass; and using a Hough transform detection method to detect a straight line in the disturbance signal distribution image, performing fitting according to the principle of relevance of tunnel engineering design to acquire a detected location of the tunnel. In this way, inverted detection and positioning of a strip-like subterranean tunnel in a mountain environment is achieved.

### TECHNICAL FIELD

The present invention pertains to the field combining theories of the discipline of geophysics and remote sensing technology, and specifically relates to methods and systems for inverted detection and positioning of a strip-like subterranean tunnel in a mountain mass.

### BACKGROUND

With the continuous advancement of urban modernization, in order to ensure the sustainable utilization of land resources, the development and utilization of subterranean space has received extensive attention. The subterranean space includes valuable natural resources and strategic resource, includes types such as subterranean buildings and projects, artificial/natural caves, etc., and, compared with ground facilities, is better concealed, more thermally stable, and more economical. The development of the subterranean space mainly refers to construction of typical subterranean targets such as artificial subterranean buildings and tunnel projects, which can be seen everywhere in daily life, such as traffic tunnels, subterranean passages, subterranean supermarkets, and subterranean parking lots. The study on detection of subterranean targets can not only find out the internal conditions of the subterranean space, but also facilitate planning and construction of the subterranean space, and facilitate improvement of methods for designing subterranean facilities. The study on detection of small subterranean targets such as subterranean pipelines is also of great significance. The orientation and distribution of a pipeline can be acquired by means of detection, allowing a faulty position on the pipeline to be located promptly. By detecting a subterranean pipeline built without authorization, illegal acts can be detected and stopped promptly, thereby improving urban management. Hence, it is definitely necessary to carry out the study on inverted detection of a strip-like subterranean tunnel in a mountain mass.

Currently, the typical methods used in the study on the method of using infrared imaging technology to detect a strip-like subterranean tunnel in a mountain mass comprise: using a multi-temporal infrared image to analyze a pattern of change in a target signal with time, and establishing a mathematical model to calculate the position of a tunnel. Alternatively, microwave infrared enhancement techniques are used. An infrared image is enhanced according to a mathematical model of microwave power transmission, so as to increase the target/background signal strength contrast to perform detection of the position of a strip-like subterranean tunnel in a mountain mass.

Disclosed in the prior art is an infrared imaging-based method for detection and location of a tunnel target in a mountain environment. Statistical analysis is performed on infrared images of a mountainous region. A signature pattern of formation of a mountain mass having a subterranean tunnel and a nearby mountain mass having no subterranean tunnel is identified. An infrared image of a mountain environment, in which a tunnel may be contained, is traversed in a certain direction to identify the signature pattern, thereby detecting and locating the tunnel target.

Also disclosed in the prior art is a method for detection and positioning of a strip-like subterranean tunnel in a mountain mass. An emulated mountain mass background thermal radiation field in which a strip-like object is located is established. Linear mapping between the emulated mountain mass background thermal radiation field and an infrared remote sensing image of a mountain mass where the target is located is performed to acquire a mountain mass background thermal radiation model. The emulated mountain mass background thermal radiation field is filtered out from the infrared remote sensing image of the mountain mass where the target is located, so as to acquire a strip-like target information field.

However, the above methods have the following defects: 1. The number of required infrared remote sensing data samples is large, and it is difficult to acquire the infrared remote sensing data samples. 2. It is difficult the apply the methods to detection of other types of targets, and environmental conditions and background characteristics affect detection results of the methods. 3. The mountain mass background thermal radiation field is emulated and calculated, but in a real-life environment, disturbance generated by a tunnel is conducted in the form of heat flow. 4. Effects of the external environment on tunnels are not fully taken into account, for example, disturbances and discrepancies in infrared data caused by vegetation on the earth surface, solar radiation, and terrain factors.

### SUMMARY OF THE INVENTION

For the defects in the prior art, an objective of the present invention is to provide a method and system for inverted detection and positioning of a strip-like subterranean tunnel in a mountain mass, aiming to solve the existing problem in which inverted detection and positioning cannot be effectively performed because signals of a tunnel in an infrared image is weakened after being conducted and modulated in a stratum.

To achieve the above objective, in an aspect, provided in the present invention is a method for inverted detection and positioning of a strip-like subterranean tunnel in a mountain mass, comprising the steps of:

(1) using a model of thermal radiation between the mountain mass and an air layer in conjunction with DEM data to calculate mountain mass surface solar radiation energy, and iteratively calculate each layer of background heat flow field energy of the mountain mass; and calculating mountain mass background heat propagation energy with reference to hyperspectral data;

(2) filtering out the mountain mass surface solar radiation energy and the mountain mass background heat propagation energy in an infrared remote sensing image;

(3) on the basis of step (2), using a subterranean target inversion model to filter out each layer of background heat flow field energy of the mountain mass in the infrared remote sensing image, and acquiring an optimal elevation of the strip-like subterranean tunnel in the mountain mass and a disturbance signal distribution image constructed via strip-like subterranean tunnel heat flow field energy in each layer of the mountain mass; and

(4) using a Hough transform detection method to detect a straight line in the disturbance signal distribution image, processing a strip-like discontinuous disturbance signal pattern according to the principle of relevance of tunnel engineering design, and performing fitting to acquire the orientation and topography of a tunnel target;

wherein the model of thermal radiation between the mountain mass and the air layer comprises an along-tunnel thermal energy radiation model, a total solar radiation energy distribution model, and a mountain mass background heat propagation model;

the along-tunnel thermal energy radiation model is constructed by using COMSOL finite element emulation software in conjunction with DEM data and a meteorological parameter, and is used for calculating along-tunnel thermal energy radiation distribution;

the total solar radiation energy distribution model is used for calculating the mountain mass surface solar radiation energy by using a hemispherical viewshed method in conjunction with the DEM data and geographic location information of the mountain mass and the tunnel;

the mountain mass background heat propagation model is used for calculating earth surface vegetation infrared radiation distribution according to a SVAT model in conjunction with the hyperspectral data.

Further preferably, a method for constructing the along-tunnel thermal energy radiation model comprises:

constructing the same on the basis of the DEM data and by using the COMSOL finite element emulation software and an energy conservation equation in a mountain mass-tunnel coupling model heat transfer process in conjunction with a tunnel surface boundary condition, thermal balance present on a contact surface between an outer surface of the tunnel and a rock formation of the mountain mass, and heat conduction flux into which a shape factor is introduced.

Further preferably, a method for calculating the mountain mass surface solar radiation energy comprises the steps of:

calculating a hemispherical viewshed according to each grid of the DEM data;

combining the hemispherical viewshed, the position of the sun, and sky information, and acquiring direct solar radiation distribution and diffuse solar radiation distribution at the grid according to a direct solar radiation amount and a diffuse solar radiation amount at the grid;

superimposing the direct solar radiation distribution and the diffuse solar radiation distribution at the grid to acquire a total amount of solar radiation received by the earth surface at the grid; and adding the total amounts of solar radiation received by the earth surface at all of the grids to acquire the mountain mass surface solar radiation energy.

Further preferably, a method for calculating each layer of background heat flow field energy in step (3) is:

E(x,y,t)=∫_{z1(x,y)}^{z2(x,y)}HF(x,y,z,t)·A(z)·ε(z)dz

HF (x, y, z, t) being heat flux per unit area in the mountain mass, A(z) and ε(z) being respectively a cross-sectional area and a heat flow attenuation coefficient at a certain elevation in the mountain mass, z1(x, y) and z2(x, y) being respectively mountain mass surface elevation coordinates and elevation coordinates at a certain depth below the surface, and z2(x, y) being adjusted to calculate the heat flow field energy contained in the mountain mass backgrounds of different thicknesses;

the heat flux per unit area is as follows:

$$H F = {c}_{m} k \frac{\partial T}{\partial h}$$

cₘ being a volumetric heat capacity of a rock formation medium, k being the thermal conductivity of the rock formation medium, and

$$\frac{\partial T}{\partial h}$$

being a vertical temperature gradient.

Further preferably, step (3) specifically comprises the steps of:

a. calculating a mountain mass total radiation amount error according to an actual total radiation amount of the earth surface of the mountain mass and a total radiation amount on the infrared remote sensing image;

$$J ( a ) = {\sum }_{i = 1}^{n} {[ E {c}_{i} - E {t}_{i} ]}^{2} \leq ε$$

ε representing an error range, and being a very small positive number, Ecᵢ representing background heat flow field energy of the mountain mass at an elevation aₖ corresponding to the i-th pixel point, and Etᵢ representing use of a total radiation amount of the i-th pixel point on the infrared remote sensing image, wherein during imaging performed by means of infrared remote sensing, interference from a sensor and an external environment incurs an error to a measured actual earth surface radiation amount, so that the mountain mass surface radiation amount acquired on the basis of the infrared remote sensing image is a combination of the actual earth surface radiation amount and an error item, as shown by the equation:

Etᵢ=Emᵢ+σ

Emᵢ representing the actual total radiation amount of the earth surface of the mountain mass of the i-th pixel point, and σ representing a measurement error item,
wherein when the measurement error is taken into account, a condition of convergence may be expressed as:

$$J ( a ) = {\sum }_{i = 1}^{n} {[ E {c}_{i} - E {t}_{i} ]}^{2} \leq n {σ}^{2}$$

b. using an elevation aₖ of the tunnel as a variable to be inverted, setting an initial value of k to 1, and initializing a₁;

c. subtracting, from a total radiation amount of each pixel point on the current infrared remote sensing image, background heat flow field energy of the mountain mass at the elevation aₖ corresponding to the each pixel point and calculating a quadratic sum to acquire strip-like subterranean tunnel heat flow field energy of the mountain mass at the elevation aₖ;

$$J ( {a}_{k} ) = {\sum }_{i = 1}^{n} {[ E {c}_{ik} - {Et}_{ik} ]}^{2}$$

aₖ and n respectively representing the tunnel elevation and the number of pixel points in a calculation region, Ecᵢ representing background heat flow field energy of the mountain mass corresponding to the i-th pixel point at the elevation aₖ, and Etᵢ representing use of a total radiation amount of the i-th pixel point on the infrared remote sensing image;

d. using the elevation aₖ of the tunnel of a current iteration and a search step and a search direction of the current iteration to determine an elevation aₖ₊₁ of a next iteration, wherein the search direction of the current iteration is calculated by using a search direction of a previous iteration, the strip-like subterranean tunnel heat flow field energy of the mountain mass at the elevation aₖ, and a conjugate parameter;

aₖ₊₁=aₖ+λₖdₖ

aₖ representing the k-th calculated value of the tunnel elevation a, λₖ representing the search step, and dₖ representing the search direction;

dₖ=∇J(aₖ)+βₖdₖ₋₁

where ∇J(aₖ) represents the gradient of the strip-like subterranean tunnel heat flow field energy of the mountain mass at the elevation aₖ, and may be calculated by means of central difference approximation, and βₖ represents the conjugate parameter;

e. using the elevation aₖ₊₁ of the next iteration as the elevation of the current iteration and returning to step c until the strip-like subterranean tunnel heat flow field energy of the mountain mass at the elevation aₖ is equal to the mountain mass total radiation amount error, and ending the iteration; and

f. constructing the disturbance signal distribution image according to the strip-like subterranean tunnel heat flow field energy in the mountain mass in each iteration, and using the elevation aₖ as the optimal elevation of the strip-like subterranean tunnel in the mountain mass.

Further preferably, a method for calculating the direct solar radiation amount E_{dir} is:

E_{dir}=ΣE_{dir}(θ,α)

E_{dir}(θ,α)=S_{const}*τ_{b}^{m(θ)}*SD_{θ,α}*SunG_{θ,α} cos(AngI(θ,α))

m(θ)=^{-0.000118*h-1.638*10}^{^{−9}}^{*h}^{²}/cos(θ)

AngI(θ,α)=arc cos(cos(θ)*cos(G_{z})+sin(θ)*sin(G_{z})*cos(α−G_{α}))

S_{const} being a solar constant, τ_{b} being atmospheric transmittance in a shortest path, m(θ) being an optical path length, SD_{θ,α} being a duration, SunG_{θ,α} being a porosity of a solar atlas sector, AngI(θ,α) being an angle of incidence of a sky sector centroid relative to a mountain mass surface perpendicular line, G_{z} and G_{α} being respectively a zenith angle and an azimuth angle of the mountain mass surface, θ₁ and θ₂ being respectively zenith angles at two boundary locations of a sky sector, and h being an elevation value;

a method for calculating the diffuse solar radiation amount E_{dif} is:

E_{dif}=ΣE_{dif}(θ,α)

E_{dif}(θ,α)=E_{glb}*p*t_{c}*SkyG_{θ,α}W(θ,α)*cos(AngI(θ,α))

E_{glb}=(S_{const}τ(τ_{b}^{m(θ)})/(1−p)

W(θ,α)=(cos θ₂−cos θ₁)/Div_{azi}

S_{const} being the solar constant, AngI(θ, α) being the angle of incidence of the sky sector centroid relative to the surface perpendicular line, E_{glb} being a normal total radiation amount, p being a ratio of diffuse radiation flux, SkyG_{θ, α} being a porosity of the sky sector, h being an elevation value, θ₁ and θ₂ being respectively the zenith angles at the two boundary locations of the sky sector, Div_{azi} being the number of azimuthal divisions of a sky atlas, W(θ, α) being the ratio of a sky sector diffuse radiation amount to a total sector diffuse radiation amount, t_{c} being a duration of diffuse solar radiation, τ_{b} being the atmospheric transmittance in the shortest path, and E_{dir}(θ, α) and E_{dif}(θ, α) being respectively direct radiation energy and diffuse radiation energy at a centroid where an observation point is located, with a zenith angle being θ and an azimuth angle being α.

In another aspect, provided in the present invention is a system for inverted detection and positioning of a strip-like subterranean tunnel in a mountain mass, comprising:

a mountain mass background heat flow field calculation module, using a model of thermal radiation between the mountain mass and an air layer in conjunction with DEM data to calculate mountain mass surface solar radiation energy, and iteratively calculate each layer of background heat flow field energy of the mountain mass; and calculating mountain mass background heat propagation energy with reference to hyperspectral data;

a disturbance signal distribution image construction module, used for filtering out the mountain mass surface solar radiation energy and the mountain mass background heat propagation energy in an infrared remote sensing image; and then using a subterranean target inversion model to filter out each layer of background heat flow field energy of the mountain mass in the infrared remote sensing image, and acquiring an optimal elevation of the strip-like subterranean tunnel in the mountain mass and a disturbance signal distribution image constructed via strip-like subterranean tunnel heat flow field energy in each layer of the mountain mass; and

a target detection location fitting module, using a Hough transform detection method to detect a straight line in the disturbance signal distribution image, processing a discontinuous disturbance signal of the strip-like subterranean tunnel in the mountain mass according to the principle of relevance of tunnel engineering design, and performing fitting to acquire the orientation and topography of the tunnel;

wherein the mountain mass background heat flow field calculation module comprises an along-tunnel thermal energy radiation distribution construction unit, a total solar radiation energy distribution construction unit, and a mountain mass background heat propagation distribution construction unit;

the along-tunnel thermal energy radiation distribution construction unit is used for constructing an along-tunnel thermal energy radiation model by using COMSOL finite element emulation software in conjunction with DEM data and a meteorological parameter;

the total solar radiation energy distribution construction unit is used for constructing a total solar radiation energy distribution model by using a hemispherical viewshed method in conjunction with the DEM data and geographic location information of the mountain mass and the tunnel, the total solar radiation energy distribution model being used for calculating the mountain mass surface solar radiation energy;

the mountain mass background heat propagation distribution construction unit is used for constructing a mountain mass background heat propagation model according to a SVAT model in conjunction with the hyperspectral data.

Further preferably, a method for constructing the along-tunnel thermal energy radiation model comprises:

constructing the same on the basis of the DEM data and by using the COMSOL finite element emulation software and an energy conservation equation in a mountain mass-tunnel coupling model heat transfer process in conjunction with a tunnel surface boundary condition, thermal balance present on a contact surface between an outer surface of the tunnel and a rock formation of the mountain mass, and heat conduction flux into which a shape factor is introduced.

Further preferably, a method for calculating the mountain mass surface solar radiation energy comprises the steps of:

calculating a hemispherical viewshed according to each grid of the DEM data;

combining the hemispherical viewshed, the position of the sun, and sky information, and acquiring direct solar radiation distribution and diffuse solar radiation distribution at the grid according to direct solar radiation energy and diffuse solar radiation energy at the grid;

superimposing the direct solar radiation distribution and the diffuse solar radiation distribution at the grid to acquire total energy of solar radiation received by the earth surface at the grid; and adding the total energy of solar radiation received by the earth surface at all of the grids to acquire the mountain mass surface solar radiation energy.

Further preferably, a calculation method for acquiring each layer of background heat flow field energy in the mountain mass is:

E(x,y,t)=∫_{z1(x,y)}^{z2(x,y)}HF(x,y,z,t)·A(z)·ε(z)dz

HF (x, y, z, t) being heat flux per unit area in the mountain mass, A(z) and ε(z) being respectively a cross-sectional area and a heat flow attenuation coefficient at a certain elevation in the mountain mass, z1(x, y) and z2(x, y) being respectively mountain mass surface elevation coordinates and elevation coordinates at a certain depth below the surface, and z2(x, y) being adjusted to calculate the heat flow field energy contained in the mountain mass backgrounds of different thicknesses;

the heat flux per unit area is as follows:

$$H F = {c}_{m} k \frac{\partial T}{\partial h}$$

cₘ being a volumetric heat capacity of a rock formation medium, k being the thermal conductivity of the rock formation medium, and

$$\frac{\partial T}{\partial h}$$

being a vertical temperature gradient.

Further preferably, a method for acquiring the optimal elevation of the strip-like subterranean tunnel in the mountain mass and the interference signal distribution image specifically comprises the steps of:

a. calculating a mountain mass total radiation amount error according to an actual total radiation amount of the earth surface of the mountain mass and a total radiation amount on the infrared remote sensing image;

$$J ( a ) = {\sum }_{i = 1}^{n} {[ E {c}_{i} - E {t}_{i} ]}^{2} \leq ε$$

ε representing an error range, and being a very small positive number, Ecᵢ representing background heat flow field energy of the mountain mass at an elevation aₖ corresponding to the i-th pixel point, and Etᵢ representing use of a total radiation amount of the i-th pixel point on the infrared remote sensing image, wherein during imaging performed by means of infrared remote sensing, interference from a sensor and an external environment incurs an error to a measured actual earth surface radiation amount, so that the mountain mass surface radiation amount acquired on the basis of the infrared remote sensing image is a combination of the actual earth surface radiation amount and an error item, as shown by the equation:

Etᵢ=Emᵢ+σ

Emᵢ representing the actual total radiation amount of the earth surface of the mountain mass of the i-th pixel point, and σ representing a measurement error item,

wherein when the measurement error is taken into account, a condition of convergence may be expressed as:

$$J ( a ) = {\sum }_{i = 1}^{n} {[ E {c}_{i} - E {t}_{i} ]}^{2} \leq n {σ}^{2}$$

b. using an elevation aₖ of the tunnel as a variable to be inverted, setting an initial value of k to 1, and initializing a₁;

c. subtracting, from a total radiation amount of each pixel point on the current infrared remote sensing image, background heat flow field energy of the mountain mass at the elevation aₖ corresponding to the each pixel point and calculating a quadratic sum to acquire strip-like subterranean tunnel heat flow field energy of the mountain mass at the elevation aₖ;

$$J ( {a}_{k} ) = {\sum }_{i = 1}^{n} {[ E {c}_{ik} - {Et}_{ik} ]}^{2}$$

aₖ and n respectively representing the tunnel elevation and the number of pixel points in a calculation region, Ecᵢ representing background heat flow field energy of the mountain mass corresponding to the i-th pixel point at the elevation aₖ, and Etᵢ representing use of a total radiation amount of the i-th pixel point on the infrared remote sensing image;

d. using the elevation aₖ of the tunnel of a current iteration and a search step and a search direction of the current iteration to determine an elevation aₖ₊₁ of a next iteration, wherein the search direction of the current iteration is calculated by using a search direction of a previous iteration, the strip-like subterranean tunnel heat flow field energy of the mountain mass at the elevation aₖ, and a conjugate parameter;

aₖ₊₁=aₖ+λₖdₖ

aₖ representing the k-th calculated value of the tunnel elevation a, λₖ representing the search step, and dₖ representing the search direction;

dₖ=∇J(aₖ)+βₖdₖ₋₁

where ∇J(aₖ) represents the gradient of the strip-like subterranean tunnel heat flow field energy of the mountain mass at the elevation aₖ, and may be calculated by means of central difference approximation, and βₖ represents the conjugate parameter;

e. using the elevation aₖ₊₁ of the next iteration as the elevation of the current iteration and returning to step c until the strip-like subterranean tunnel heat flow field energy of the mountain mass at the elevation aₖ is equal to the mountain mass total radiation amount error, and ending the iteration; and

f. constructing the disturbance signal distribution image according to the strip-like subterranean tunnel heat flow field energy in the mountain mass in each iteration, and using the elevation aₖ as the optimal elevation of the strip-like subterranean tunnel in the mountain mass.

Further preferably, a method for calculating the direct solar radiation amount E_{dir} is:

E_{dir}=ΣE_{dir}(θ,α)

E_{dir}(θ,α)=S_{const}*τ_{b}^{m(θ)}*SD_{θ,α}*SunG_{θ,α}*cos(AngI(θ,α))

AngI(θ,α)=arc cos(cos(θ)*cos(G_{z})+sin(θ)*sin(G_{z})*cos(α−Gₐ))

S_{const} being a solar constant, τ_{b} being atmospheric transmittance in a shortest path, m(θ) being an optical path length, SD_{θ,α} being a duration, SunG_{θ,α} being a porosity of a solar atlas sector, AngI(θ, α) being an angle of incidence of a sky sector centroid relative to a mountain mass surface perpendicular line, G_{z} and G_{α} being respectively a zenith angle and an azimuth angle of the mountain mass surface, θ₁ and θ₂ being respectively zenith angles at two boundary locations of a sky sector, and h being an elevation value;

a method for calculating the diffuse solar radiation energy E_{dif} is:

E_{dif}=ΣE_{dif}(θ,α)

E_{dif}(θ,α)=E_{glb}*p*t_{c}*SkyG_{θ,α}*W(θ,α)*cos(AngI(θ,α))

E_{glb}=(S_{const}Σ(τ_{b}^{m(θ)}))/(1−p)

W(θ,α)=(cos θ₂−cos θ₁)/Div_{azi}

S_{const} being the solar constant, AngI(θ, α) being the angle of incidence of the sky sector centroid relative to the surface perpendicular line, E_{glb} being normal total radiation energy, p being a ratio of diffuse radiation flux, SkyG_{θ,α} being a porosity of the sky sector, h being an elevation value, θ₁ and θ₂ being respectively the zenith angles at the two boundary locations of the sky sector, Div_{azi} being the number of azimuthal divisions of a sky atlas, W(θ, α) being the ratio of a sky sector diffuse radiation amount to a total sector diffuse radiation amount, t_{c} being a duration of diffuse solar radiation, τ_{b} being the atmospheric transmittance in the shortest path, and E_{dir}(θ, α) and E_{dif}(θ, α) being respectively a direct radiation amount and a diffuse radiation amount at a centroid where an observation point is located, with a zenith angle being θ and an azimuth angle being α.

In general, compared with the prior art, the above technical solutions conceived by the present invention have the following beneficial effects:

In the present invention, the model of thermal radiation between a mountain mass and an air layer is used in conjunction with DEM data to calculate mountain mass surface solar radiation energy, and iteratively calculate each layer of mountain mass background heat flow field of the mountain mass and tunnel and mountain mass background heat propagation energy. The effects of the external environment on the mountain mass are fully taken into account, such as discrepancies and disturbances in infrared data caused by vegetation on the earth surface, solar radiation, and terrain factors. The present invention solves the problem in which inverted detection and positioning cannot be effectively performed on a strip-like subterranean tunnel in a mountain mass because signals thereof in an infrared image is weakened after being conducted and modulated in a stratum. The invention thus achieves inverted detection and positioning of a tunnel in a mountain environment.

The present invention takes into account mountain mass surface solar radiation energy, and fully takes into account the effect of direct solar radiation and diffuse solar radiation in each DEM data grid. Compared with the method of using a multi-temporal infrared image to analyze a pattern of change in a target signal with time and establishing a mathematical model to calculate the position of a tunnel, the present invention more precisely takes into account the effects of the external environment (direct solar radiation, diffuse radiation, vegetation on the earth surface, etc.) on disturbance of energy of a strip-like subterranean tunnel in a mountain mass, such that a detection inversion result is more precise. Compared with requirements on multi-temporal infrared data in a target region, the preset method acquires data more easily. Compared with the method of performing statistical analysis on infrared images of a mountainous region, identifying a signature pattern of formation of a mountain mass having a subterranean tunnel and a nearby mountain mass having no subterranean tunnel, and identifying the signature pattern by traversing, in a certain direction, an infrared image of a mountain environment in which a tunnel may be contained, so as to detect and locate a tunnel target, the present invention does not require a selection of a large number of sample segments to determine whether a tunnel is present in a mountain mass, so that the present method has higher efficiency. Multi-source information fusion is used to filter out environmental interference, so that the precision and accuracy of inverted detection and positioning of a strip-like subterranean tunnel in a mountain mass are very high.

### BRIEF DESCRIPTION OF THE DRAWINGS

FIG. 1 is a flowchart of a method for inverted detection and positioning where interference from an environment of a strip-like subterranean tunnel in a mountain mass is filtered out according to an embodiment of the present invention;

FIG. 2 is a flowchart of a method for inverted detection according to an embodiment of the present invention; and

FIG. 3 is DEM data of the Tanyugou area according to an embodiment of the present invention;

FIG. 4 is a schematic diagram of mountain mass background temperature field distribution according to an embodiment of the present invention;

FIG. 5 is a schematic diagram of the position of an observation point according to an embodiment of the present invention;

FIG. 6 is a hemispherical viewshed at an observation point according to an embodiment of the present invention;

FIG. 7 is a schematic diagram of distribution of direct solar radiation received at an observation point according to an embodiment of the present invention;

FIG. 8 is a diagram of distribution of direct solar radiation energy received on the earth surface in the Tanyugou area according to an embodiment of the present invention;

FIG. 9 is a schematic diagram of distribution of diffuse solar radiation received at an observation point according to an embodiment of the present invention;

FIG. 10 is a diagram of distribution of diffuse solar radiation energy received by the earth surface in the Tanyugou area according to an embodiment of the present invention;

FIG. 11 is a diagram of distribution of total solar radiation energy received on the earth surface in the Tanyugou area according to an embodiment of the present invention;

FIG. 12 is a diagram of emulated infrared radiation of vegetation on a mountain mass in the Tanyugou tunnel area according to an embodiment of the present invention;

FIG. 13(a) is a resultant image of filtering out heat smooth energy contained in a mountain mass thickness of 40 m according to an embodiment of the present invention;

FIG. 13(b) is a resultant image of filtering out heat smooth energy contained in a mountain mass thickness of 80 m according to an embodiment of the present invention;

FIG. 13(c) is a resultant image of filtering out heat smooth energy contained in a mountain mass thickness of 140 m according to an embodiment of the present invention;

FIG. 13(d) is a resultant image of filtering out heat smooth energy contained in a mountain mass thickness of 180 m according to an embodiment of the present invention;

FIG. 13(e) is a resultant image of filtering out heat smooth energy contained in a mountain mass thickness of 200 m according to an embodiment of the present invention;

FIG. 14 is a diagram of a result of inverted detection and positioning in the Tanyugou tunnel area according to an embodiment of the present invention;

FIG. 15 is a schematic diagram of a straight line detection result in the Tanyugou tunnel area according to an embodiment of the present invention; and

FIG. 16 is comparison between a final detection result and the actual position of the Tanyugou tunnel according to an embodiment of the present invention.

### DETAILED DESCRIPTION

To make the purpose, technical solution, and advantages of the present invention clearer, the present invention is further described in detail below in connection with the accompanying drawings and embodiments. It should be appreciated that the specific embodiments described here are used merely to explain the present invention and are not used to define the present invention.

Provided in the present invention is a method for inverted detection and positioning of a strip-like subterranean tunnel in a mountain mass with environmental interference filtered out, the method including the steps of:

using DEM data of a region corresponding to an infrared image to calculate total solar radiation energy received by the mountain mass surface;

calculating along-tunnel thermal energy radiation distribution with reference to the DEM data, a property parameter of medium material in the tunnel in the mountain mass, and a meteorological parameter;

using a SVAT model in conjunction with hyperspectral image data to calculate mountain mass background heat propagation energy distribution; and

implementing inverted detection and positioning of a strip-like target with environmental interference filtered out.

Specifically:

In an aspect, provided in the present invention is a method for inverted detection and positioning of a strip-like subterranean tunnel in a mountain mass, including the steps of:

(1) using a model of thermal radiation between the mountain mass and an air layer in conjunction with DEM data to calculate mountain mass surface solar radiation energy, and iteratively calculate each layer of background heat flow field energy of the mountain mass; and calculating mountain mass background heat propagation energy with reference to hyperspectral data;

(2) filtering out the mountain mass surface solar radiation energy and the mountain mass background heat propagation energy in an infrared remote sensing image;

(3) on the basis of step (2), using a subterranean target inversion model to filter out each layer of background heat flow field energy of the mountain mass in the infrared remote sensing image, and acquiring an optimal elevation of the strip-like subterranean tunnel in the mountain mass and a disturbance signal distribution image constructed via strip-like subterranean tunnel heat flow field energy in each layer of the mountain mass; and

(4) using a Hough transform detection method to detect a straight line in the disturbance signal distribution image, processing a strip-like discontinuous disturbance signal pattern according to the principle of relevance of tunnel engineering design, and performing fitting to acquire the orientation and topography of a tunnel target;

wherein the model of thermal radiation between the mountain mass and the air layer includes an along-tunnel thermal energy radiation model, a total solar radiation energy distribution model, and a mountain mass background heat propagation model;

the along-tunnel thermal energy radiation model is constructed by using COMSOL finite element emulation software in conjunction with DEM data and a meteorological parameter, and is used for calculating along-tunnel thermal energy radiation distribution;

the total solar radiation energy distribution model is used for calculating the mountain mass surface solar radiation energy by using a hemispherical viewshed method in conjunction with the DEM data and geographic location information of the mountain mass and the tunnel;

the mountain mass background heat propagation model is used for calculating earth surface vegetation infrared radiation distribution according to a SVAT model in conjunction with the hyperspectral data.

Further preferably, a method for constructing the along-tunnel thermal energy radiation model comprises:

constructing the same with reference to the DEM data and by using the COMSOL finite element emulation software and an energy conservation equation in a mountain mass-tunnel coupling model heat transfer process in conjunction with a tunnel surface boundary condition, thermal balance present on a contact surface between an outer surface of the tunnel and a rock formation of the mountain mass, and heat conduction flux into which a shape factor is introduced.

Further preferably, a method for calculating the mountain mass surface solar radiation energy includes the steps of:

calculating a hemispherical viewshed according to each grid of the DEM data;

combining the hemispherical viewshed, the position of the sun, and sky information, and acquiring direct solar radiation distribution and diffuse solar radiation distribution at the grid according to a direct solar radiation amount and a diffuse solar radiation amount at the grid;

superimposing the direct solar radiation distribution and the diffuse solar radiation distribution at the grid to acquire a total amount of solar radiation received by the earth surface at the grid; and adding the total amounts of solar radiation received by the earth surface at all of the grids to acquire the mountain mass surface solar radiation energy.

Further preferably, a method for calculating each layer of background heat flow field energy in step (3) is:

E(x,y,t)=∫_{z1(x,y)}^{z2(x,y)}HF(x,y,z,t)·A(z)·ε(z)dz

HF (x, y, z, t) being heat flux per unit area in the mountain mass, A(z) and ε(z) being respectively a cross-sectional area and a heat flow attenuation coefficient at a certain elevation in the mountain mass, z1(x, y) and z2(x, y) being respectively mountain mass surface elevation coordinates and elevation coordinates at a certain depth below the surface, and z2(x, y) being adjusted to calculate the heat flow field energy contained in the mountain mass backgrounds of different thicknesses;

the heat flux per unit area is as follows:

$$H F = {c}_{m} k \frac{\partial T}{\partial h}$$

cₘ being a volumetric heat capacity of a rock formation medium, k being the thermal conductivity of the rock formation medium, and

$$\frac{\partial T}{\partial h}$$

being a vertical temperature gradient.

Further preferably, step (3) specifically includes the steps of:

a. calculating a mountain mass total radiation amount error according to an actual total radiation amount of the earth surface of the mountain mass and a total radiation amount on the infrared remote sensing image;

$$J ( a ) = {\sum }_{i = 1}^{n} {[ E {c}_{i} - E {t}_{i} ]}^{2} \leq ε$$

ε representing an error range, and being a very small positive number, Ecᵢ representing background heat flow field energy of the mountain mass at an elevation aₖ corresponding to the i-th pixel point, and Etᵢ representing use of a total radiation amount of the i-th pixel point on the infrared remote sensing image, wherein during imaging performed by means of infrared remote sensing, interference from a sensor and an external environment incurs an error to a measured actual earth surface radiation amount, so that the mountain mass surface radiation amount acquired on the basis of the infrared remote sensing image is a combination of the actual earth surface radiation amount and an error item, as shown by the equation:

Etᵢ=Emᵢ+σ

Emᵢ representing the actual total radiation amount of the earth surface of the mountain mass of the i-th pixel point, and σ representing a measurement error item, wherein when the measurement error is taken into account, a condition of convergence may be expressed as:

$$J ( a ) = {\sum }_{i = 1}^{n} {[ E {c}_{i} - E {t}_{i} ]}^{2} \leq n {σ}^{2}$$

b. using an elevation aₖ of the tunnel as a variable to be inverted, setting an initial value of k to 1, and initializing a₁;

c. subtracting, from a total radiation amount of each pixel point on the current infrared remote sensing image, background heat flow field energy of the mountain mass at the elevation aₖ corresponding to the each pixel point and calculating a quadratic sum to acquire strip-like subterranean tunnel heat flow field energy of the mountain mass at the elevation aₖ;

$$J ( {a}_{k} ) = {\sum }_{i = 1}^{n} {[ {Ec}_{ik} - {Et}_{ik} ]}^{2}$$

aₖ and n respectively representing the tunnel elevation and the number of pixel points in a calculation region, Ecᵢ representing background heat flow field energy of the mountain mass corresponding to the i-th pixel point at the elevation aₖ, and Etᵢ representing use of a total radiation amount of the i-th pixel point on the infrared remote sensing image;

d. using the elevation aₖ of the tunnel of a current iteration and a search step and a search direction of the current iteration to determine an elevation aₖ₊₁ of a next iteration, wherein the search direction of the current iteration is calculated by using a search direction of a previous iteration, the strip-like subterranean tunnel heat flow field energy of the mountain mass at the elevation aₖ, and a conjugate parameter;

aₖ₊₁=aₖ+λₖdₖ

aₖ representing the k-th calculated value of the tunnel elevation a, λₖ representing the search step, and dₖ representing the search direction;

dₖ=∇J(aₖ)+βₖdₖ₋₁

where ∇J(aₖ) represents the gradient of the strip-like subterranean tunnel heat flow field energy of the mountain mass at the elevation aₖ, and may be calculated by means of central difference approximation, and βₖ represents the conjugate parameter;

e. using the elevation aₖ₊₁ of the next iteration as the elevation of the current iteration and returning to step c until the strip-like subterranean tunnel heat flow field energy of the mountain mass at the elevation aₖ is equal to the mountain mass total radiation amount error, and ending the iteration; and

f. constructing the disturbance signal distribution image according to the strip-like subterranean tunnel heat flow field energy in the mountain mass in each iteration, and using the elevation aₖ as the optimal elevation of the strip-like subterranean tunnel in the mountain mass.

Further preferably, a method for calculating the direct solar radiation amount E_{dir} is:

E_{dir}=ΣE_{dir}(θ,α)

E_{dir}(θ,α)=S_{const}*τ_{b}^{m(θ)}*SD_{θ,α}*SunG_{θ,α} cos(AngI(θ,α))

m(θ)=^{-0.000118*h-1.638*10}^{^{−9}}^{*h}^{²}/cos(θ)

AngI(θ,α)=arc cos(cos(θ)*cos(G_{z})+sin(θ)*sin(G_{z})*cos(α−G_{α}))

S_{const} being a solar constant, τ_{b} being atmospheric transmittance in a shortest path, m(θ) being an optical path length, SD_{θ,α} being a duration, SunG_{θ,α} being a porosity of a solar atlas sector, AngI(θ,α) being an angle of incidence of a sky sector centroid relative to a mountain mass surface perpendicular line, G_{z} and G_{α} being respectively a zenith angle and an azimuth angle of the mountain mass surface, θ₁ and θ₂ being respectively zenith angles at two boundary locations of a sky sector, and h being an elevation value;

a method for calculating the diffuse solar radiation amount E_{dif} is:

E_{dif}=ΣE_{dif}(θ,α)

E_{dif}(θ,α)=E_{glb}*p*t_{c}*SkyG_{θ,α}W(θ,α)*cos(AngI(θ,α))

E_{glb}=(S_{const}τ(τ_{b}^{m(θ)})/(1−p)

W(θ,α)=(cos θ₂−cos θ₁)/Div_{azi}

S_{const} being the solar constant, AngI(θ, α) being the angle of incidence of the sky sector centroid relative to the surface perpendicular line, E_{glb} being a normal total radiation amount, p being a ratio of diffuse radiation flux, SkyG_{θ, α} being a porosity of the sky sector, h being an elevation value, θ₁ and θ₂ being respectively the zenith angles at the two boundary locations of the sky sector, Div_{azi} being the number of azimuthal divisions of a sky atlas, W(θ, α) being the ratio of a sky sector diffuse radiation amount to a total sector diffuse radiation amount, t_{c} being a duration of diffuse solar radiation, τ_{b} being the atmospheric transmittance in the shortest path, and E_{dir}(θ, α) and E_{dif}(θ, α) being respectively direct radiation energy and diffuse radiation energy at a centroid where an observation point is located, with a zenith angle being θ and an azimuth angle being α.

In another aspect, provided in the present invention is a system for inverted detection and positioning of a strip-like subterranean tunnel in a mountain mass, including:

a mountain mass background heat flow field calculation module, using a model of thermal radiation between the mountain mass and an air layer in conjunction with DEM data to calculate mountain mass surface solar radiation energy, and iteratively calculate each layer of background heat flow field energy of the mountain mass; and calculating mountain mass background heat propagation energy with reference to hyperspectral data;

a disturbance signal distribution image construction module, used for filtering out the mountain mass surface solar radiation energy and the mountain mass background heat propagation energy in an infrared remote sensing image; and then using a subterranean target inversion model to filter out each layer of background heat flow field energy of the mountain mass in the infrared remote sensing image, and acquiring an optimal elevation of the strip-like subterranean tunnel in the mountain mass and a disturbance signal distribution image constructed via strip-like subterranean tunnel heat flow field energy in each layer of the mountain mass; and

a target detection location fitting module, using a Hough transform detection method to detect a straight line in the disturbance signal distribution image, processing a discontinuous disturbance signal of the strip-like subterranean tunnel in the mountain mass according to the principle of relevance of tunnel engineering design, and performing fitting to acquire the orientation and topography of the tunnel;

wherein the mountain mass background heat flow field calculation module includes an along-tunnel thermal energy radiation distribution construction unit, a total solar radiation energy distribution construction unit, and a mountain mass background heat propagation distribution construction unit;

the along-tunnel thermal energy radiation distribution construction unit is used for constructing an along-tunnel thermal energy radiation model by using COMSOL finite element emulation software in conjunction with DEM data and a meteorological parameter;

the total solar radiation energy distribution construction unit is used for constructing a total solar radiation energy distribution model by using a hemispherical viewshed method in conjunction with the DEM data and geographic location information of the mountain mass and the tunnel, the total solar radiation energy distribution model being used for calculating the mountain mass surface solar radiation energy;

the mountain mass background heat propagation distribution construction unit is used for constructing a mountain mass background heat propagation model according to a SVAT model in conjunction with the hyperspectral data.

Further preferably, a method for constructing the along-tunnel thermal energy radiation model comprises:

constructing the same on the basis of the DEM data and by using the COMSOL finite element emulation software and an energy conservation equation in a mountain mass-tunnel coupling model heat transfer process in conjunction with a tunnel surface boundary condition, thermal balance present on a contact surface between an outer surface of the tunnel and a rock formation of the mountain mass, and heat conduction flux into which a shape factor is introduced.

Further preferably, a method for calculating the mountain mass surface solar radiation energy includes the steps of:

calculating a hemispherical viewshed according to each grid of the DEM data;

combining the hemispherical viewshed, the position of the sun, and sky information, and acquiring direct solar radiation distribution and diffuse solar radiation distribution at the grid according to direct solar radiation energy and diffuse solar radiation energy at the grid;

superimposing the direct solar radiation distribution and the diffuse solar radiation distribution at the grid to acquire total energy of solar radiation received by the earth surface at the grid; and

adding the total energy of solar radiation received by the earth surface at all of the grids to acquire the mountain mass surface solar radiation energy.

Further preferably, a method for acquiring the optimal elevation of the strip-like subterranean tunnel in the mountain mass and the interference signal distribution image specifically includes the steps of:

a. calculating a mountain mass total radiation amount error according to an actual total radiation amount of the earth surface of the mountain mass and a total radiation amount on the infrared remote sensing image;

$$J ( a ) = {\sum }_{i = 1}^{n} {[ {Ec}_{i} - {Et}_{i} ]}^{2} \leq ε$$

ε representing an error range, and being a very small positive number, Ecᵢ representing background heat flow field energy of the mountain mass at an elevation aₖ corresponding to the i-th pixel point, and Etᵢ representing use of a total radiation amount of the i-th pixel point on the infrared remote sensing image, wherein during imaging performed by means of infrared remote sensing, interference from a sensor and an external environment incurs an error to a measured actual earth surface radiation amount, so that the mountain mass surface radiation amount acquired on the basis of the infrared remote sensing image is a combination of the actual earth surface radiation amount and an error item, as shown by the equation:

Etᵢ=Emᵢ+σ

Emᵢ representing the actual total radiation amount of the earth surface of the mountain mass of the i-th pixel point, and σ representing a measurement error item, wherein when the measurement error is taken into account, a condition of convergence may be expressed as:

$$J ( a ) = {\sum }_{i = 1}^{n} {[ {Ec}_{i} - {Et}_{i} ]}^{2} \leq n {σ}^{2}$$

b. using an elevation aₖ of the tunnel as a variable to be inverted, setting an initial value of k to 1, and initializing a₁;

c. subtracting, from a total radiation amount of each pixel point on the current infrared remote sensing image, background heat flow field energy of the mountain mass at the elevation aₖ corresponding to the each pixel point and calculating a quadratic sum to acquire strip-like subterranean tunnel heat flow field energy of the mountain mass at the elevation aₖ;

$$J ( {a}_{k} ) = {\sum }_{i = 1}^{n} {[ {Ec}_{ik} - {Et}_{ik} ]}^{2}$$

aₖ and n respectively representing the tunnel elevation and the number of pixel points in a calculation region, Ecᵢ representing background heat flow field energy of the mountain mass corresponding to the i-th pixel point at the elevation aₖ, and Etᵢ representing use of a total radiation amount of the i-th pixel point on the infrared remote sensing image;

d. using the elevation aₖ of the tunnel of a current iteration and a search step and a search direction of the current iteration to determine an elevation aₖ₊₁ of a next iteration, wherein the search direction of the current iteration is calculated by using a search direction of a previous iteration, the strip-like subterranean tunnel heat flow field energy of the mountain mass at the elevation aₖ, and a conjugate parameter;

aₖ₊₁=aₖ+λₖdₖ

aₖ representing the k-th calculated value of the tunnel elevation a, λₖ representing the search step, and dₖ representing the search direction;

dₖ=∇J(aₖ)+βₖdₖ₋₁

where ∇J(aₖ) represents the gradient of the strip-like subterranean tunnel heat flow field energy of the mountain mass at the elevation aₖ, and may be calculated by means of central difference approximation, and βₖ represents the conjugate parameter;

e. using the elevation aₖ₊₁ of the next iteration as the elevation of the current iteration and returning to step c until the strip-like subterranean tunnel heat flow field energy of the mountain mass at the elevation aₖ is equal to the mountain mass total radiation amount error, and ending the iteration; and

f. constructing the disturbance signal distribution image according to the strip-like subterranean tunnel heat flow field energy in the mountain mass in each iteration, and using the elevation aₖ as the optimal elevation of the strip-like subterranean tunnel in the mountain mass.

Further preferably, a method for calculating the direct solar radiation amount E_{dir} is:

E_{dir}=ΣE_{dir}(θ,α)

E_{dir}(θ,α)=S_{const}*τ_{b}^{m(θ)}*SD_{θ,α}*SunG_{θ,α} cos(AngI(θ,α))

m(θ)=^{-0.000118*h-1.638*10}^{^{−9}}^{*h}^{²}/cos(θ)

AngI(θ,α)=arc cos(cos(θ)*cos(G_{z})+sin(θ)*sin(G_{z})*cos(α−G_{α}))

S_{const} being a solar constant, τ_{b} being atmospheric transmittance in a shortest path, m(θ) being an optical path length, SD_{θ,α} being a duration, SunG_{θ,α} being a porosity of a solar atlas sector, AngI(θ,α) being an angle of incidence of a sky sector centroid relative to a mountain mass surface perpendicular line, G_{z} and G_{α} being respectively a zenith angle and an azimuth angle of the mountain mass surface, θ₁ and θ₂ being respectively zenith angles at two boundary locations of a sky sector, and h being an elevation value;

a method for calculating the diffuse solar radiation amount E_{dif} is:

E_{dif}=ΣE_{dif}(θ,α)

E_{dif}(θ,α)=E_{glb}*p*t_{c}*SkyG_{θ,α}W(θ,α)*cos(AngI(θ,α))

E_{glb}=(S_{const}τ(τ_{b}^{m(θ)})/(1−p)

W(θ,α)=(cos θ₂−cos θ₁)/Div_{azi}

S_{const} being the solar constant, AngI(θ, α) being the angle of incidence of the sky sector centroid relative to the surface perpendicular line, E_{glb} being a normal total radiation energy, p being a ratio of diffuse radiation flux, SkyG_{θ, α} being a porosity of the sky sector, h being an elevation value, θ₁ and θ₂ being respectively the zenith angles at the two boundary locations of the sky sector, Div_{azi} being the number of azimuthal divisions of a sky atlas, W(θ, α) being the ratio of a sky sector diffuse radiation amount to a total sector diffuse radiation amount, t_{c} being a duration of diffuse solar radiation, τ_{b} being the atmospheric transmittance in the shortest path, and E_{dir}(θ, α) and E_{dif}(θ, α) being respectively direct radiation energy and diffuse radiation energy at a centroid where an observation point is located, with a zenith angle being θ and an azimuth angle being α.

### Embodiment

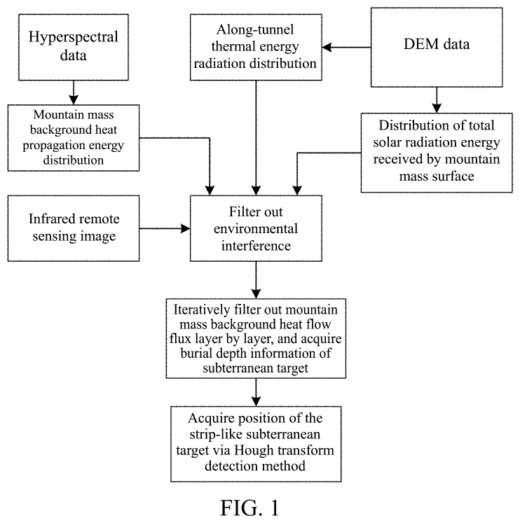

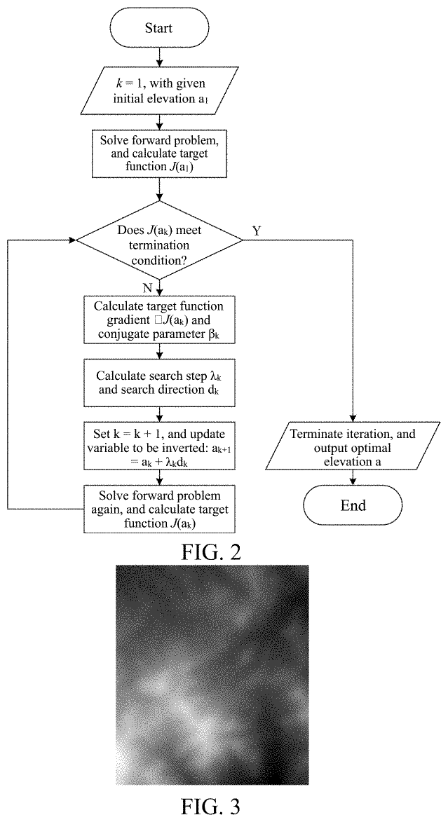

As shown in FIG. 1, provided in the present invention is a method for inverted detection and positioning of a strip-like subterranean tunnel in a mountain mass with environmental interference filtered out, including the following steps:

(1) Establishment of along-tunnel thermal energy radiation model

Guided by basic theories of the disciplines such as geophysics, heat transfer science, sensing technology, etc., the substance/energy characteristic relationship and the pattern of interaction between a subterranean tunnel and an environment of the same were analyzed, and an along-tunnel thermal energy radiation model of a target region was established. More specifically, the following steps were included:

With reference to DEM data (as shown in FIG. 3), existing software was used to perform geometric modeling and emulation on tunnel lines. In order to display along-tunnel thermal energy radiation information, COMSOL finite element emulation software was used to perform emulation and calculation on an along-tunnel thermal radiation field.

(1.1) Heat conservation in a heat transfer process in a mountain mass-tunnel coupling model may be described as:

Q_{d}+Qᵥ=Q

Qᵥ=ρCₚw·∇T

Q_{d}=−k·h·∇T

Qᵥ and Q_{d} respectively representing convection thermal flux and conduction thermal flux, Q being thermal flux inputted from the outside, ρ and Cₚ respectively representing the density of a medium and a specific heat capacity at constant pressure, w being a fluid velocity, k being the thermal conductivity of the medium, h being an elevation gradient, and ∇T being gradient change of temperature in a perpendicular direction of the tunnel in the mountain mass, which can be calculated by means of difference approximation

$$∇ T = \frac{\partial T}{\partial z} \approx \frac{Δ T}{Δ z} ,$$

where the medium is the medium contained in the tunnel in the mountain mass.
(1.2) The tunnel surface boundary condition is that the temperature in the tunnel is constant, which can be expressed as:

Tᵢₙ=f(y)=T₀

(1.3) For a contact surface between an outer surface of the tunnel and a rock formation of the mountain mass, the following thermal balance relationship is present:

$$\frac{{λ}_{c} ( {T}_{out} - {T}_{in} )}{{δ}_{c}} = \frac{{λ}_{g} ( {T}_{s} - {T}_{out} )}{{δ}_{g}}$$

Tₒᵤₜ and Tᵢₙ respectively representing the temperature on the outer surface of the tunnel and the temperature in the tunnel, Tₛ representing the temperature of the earth surface of the mountain mass, λ_{c} and δ_{c} respectively representing the thickness and the thermal conductivity coefficient of concrete between the inner surface and the outer surface of the tunnel, and λ_{g} and δ_{g} respectively representing the thickness and the thermal conductivity coefficient of granite between the outer surface of the tunnel and the earth surface.

(1.4) The longitudinal length of the tunnel is much greater than the cross-sectional radius thereof, and the calculation process may be simplified by introducing a shape factor. After the shape factor is introduced, the amount of conducted heat is calculated as follows:

$$Φ = λ S ( {T}_{1} - {T}_{2} ) \\ S = \frac{2 π / ln ( \frac{2 l}{d} )}{1 + \frac{ln ( 2 H / l )}{ln ( 2 H / d )}}$$

Φ being the amount of heat conducted by the tunnel, λ being the thermal conductivity coefficient of the material of the medium between isothermal surfaces, being the amount of heat conducted by the upper surface, T₂ being the amount of heat conducted by the lower surface, d and l respectively representing the cross-sectional radius and the overall length of the tunnel, and H representing a burial depth of the tunnel.

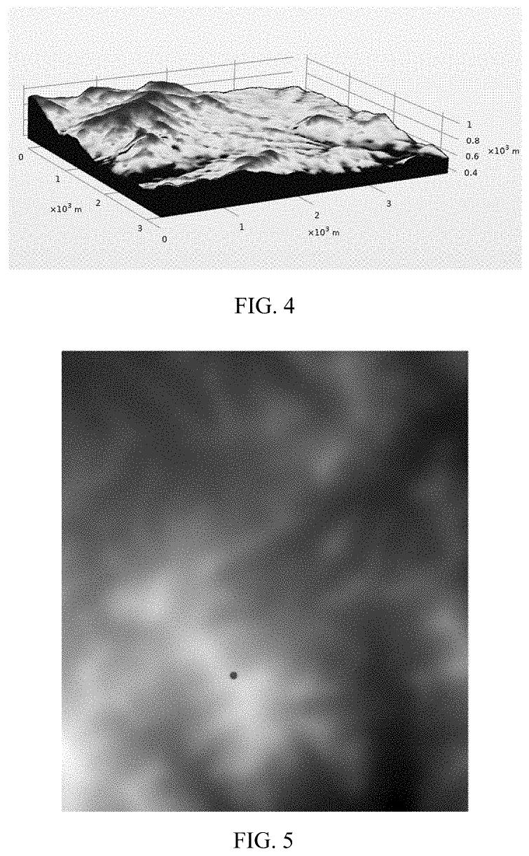

The surface temperature field distribution of the mountain mass-tunnel coupling model can be acquired by combining the calculation formulas. In the present invention, modeling, emulation, and calculation were performed on the basis of relevant parameters by using COMSOL software, thereby acquiring the ultimate three-dimensional mountain mass temperature field distribution in a Tanyugou tunnel area, as shown in FIG. 4.

### (2) Construction of Total Solar Radiation Energy Distribution Model

The mountain mass surface temperature data acquired by means of modeling, emulation, and calculation in the above process was theoretical data acquired without taking the effects of the external environment into account, and was different from actual infrared radiation data of the mountain mass surface acquired by means of an infrared remote sensing image. Therefore, two major external interference factors, i.e., solar radiation and earth surface vegetation distribution, need to be investigated, calculated, and eliminated, so as to ensure the authenticity and effectiveness of a detection result. A hemispherical viewshed method was used herein to calculate solar radiation received by the earth surface.

The solar radiation received by the earth surface mainly includes direct radiation, diffuse radiation, and reflected radiation. Since the reflected radiation accounts for a small portion, and only under special conditions, has an obvious effect on the solar radiation received by the earth surface, a solar radiation calculation model typically does not take the reflected radiation into account. Therefore, when infrared means are used to detect a subterranean target, the effect of the diffuse solar radiation and the direction solar radiation need to be fully considered.

In this embodiment, a hemispherical viewshed algorithm was used to calculate the solar radiation received by the earth surface. The basic idea of the algorithm is: a digital elevation model (DEM, which is a terrain model represented by absolute elevations) data grid is first used to calculate a hemispherical viewshed; then, direct radiation and diffuse radiation acting on the grid are determined by combining the hemispherical viewshed, the position of the sun, and sky information; and finally, calculation is performed on all DEM data grids one by one to calculate a total solar radiation amount received by the earth surface in this area.

The total solar radiation amount is acquired by adding a direct solar radiation amount and a diffuse solar radiation amount:

Eₜₒₜₐₗ=E_{dir}+E_{dif}

Eₜₒₜₐₗ being the total solar radiation amount, and E_{dir} and E_{dif} being respectively the total direct solar radiation amount and the total diffuse solar radiation amount.

The direct solar radiation amount is the sum of direct radiation in all solar atlas sectors. The diffuse radiation amount is the sum of diffuse radiation in all of the sky atlas sectors:

E_{dir}=ΣE_{dir}(θ,α)

E_{dif}=ΣE_{dif}(θ,α)

E_{dir}(θ, α) and E_{dif}(θ, α) being respectively the direct radiation amount and the diffuse radiation amount when a centroid is located at a zenith angle of θ and an azimuth angle of α.

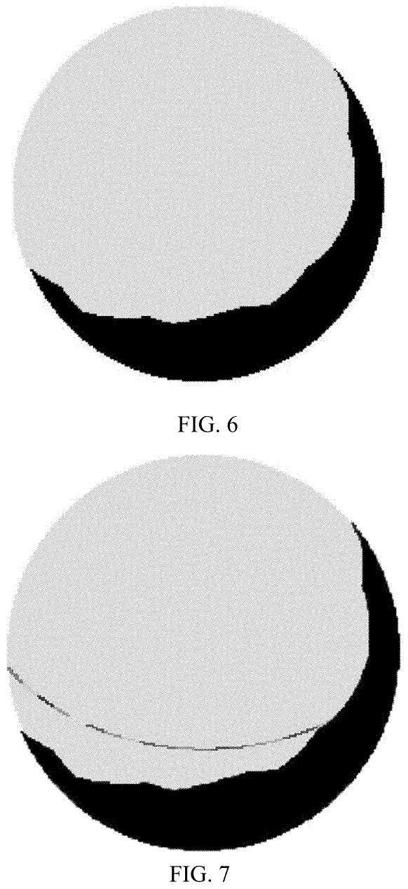

A point on a DEM image of the Tanyugou tunnel area was selected as an observation point, and the elevation of the location thereof was 980 m. The location of the observation point and the hemispherical viewshed calculation result thereof are respectively shown in FIG. 5 and FIG. 6.

(2.1) Calculation of direct solar radiation

E_{dir}=ΣE_{dir}(θ,α)

E_{dir}(θ,α)=S_{const}*τ_{b}^{m(θ)}*SD_{θ,α}*SunG_{θ,α} cos(AngI(θ,α))

m(θ)=^{-0.000118*h-1.638*10}^{^{−9}}^{*h}^{²}/cos(θ)

AngI(θ,α)=arc cos(cos(θ)*cos(G_{z})+sin(θ)*sin(G_{z})*cos(α−G_{α}))

S_{const} being a solar constant, τ_{b} being atmospheric transmittance in a shortest path, m(θ) being an optical path length, SD_{θ,α} being a duration, SunG_{θ,α} being a porosity of a solar atlas sector, AngI(θ,α) being an angle of incidence of a sky sector centroid relative to a surface perpendicular line, G_{z} and G_{α} being respectively a zenith angle and an azimuth angle of the surface, θ₁ and θ₂ being respectively zenith angles at two boundary locations of a sky sector, and h being an elevation value;

The direct solar radiation of individual sky directions can be calculated by means of the solar atlas. The solar atlas shows the motion trajectory of the sun. From the perspective of the hemispherical viewshed, the solar atlas may be divided into a plurality of discrete sectors. Each sector has a zenith angle and an azimuth angle corresponding thereto. It can be considered that the direct radiation within the sector is the same. The direct radiation in each sector is calculated, and is superimposed with the hemispherical viewshed, so that the direct radiation distribution at the observation point can be acquired, and then accumulative operation is performed to acquire the total direct solar radiation energy received at the observation point.

The solar atlas at the observation point from 12 a.m. to 3 p.m. was calculated, and in conjunction with the acquired hemispherical viewshed, the distribution of the direct solar radiation received by the observation point could be acquired, as shown in FIG. 7.

The direct solar radiation received in each location was calculated sequentially, and the distribution of the direct solar radiation energy received by the earth surface in the Tanyugou area was acquired, as shown in FIG. 8.

(2.2) Calculation of diffuse solar radiation

E_{dif}=ΣE_{dif}(θ,α)

E_{dif}(θ,α)=E_{glb}*p*t_{c}*SkyG_{θ,α}W(θ,α)*cos(AngI(θ,α))

E_{glb}=(S_{const}τ(τ_{b}^{m(θ)})/(1−p)

W(θ,α)=(cos θ₂−cos θ₁)/Div_{azi}

S_{const} being the solar constant, AngI(θ, α) being the angle of incidence of the sky sector centroid relative to the surface perpendicular line, E_{glb} being a normal total radiation amount, p being a ratio of diffuse radiation flux, SkyG_{θ, α} being a porosity of the sky sector, h being an elevation value, θ₁ and θ₂ being respectively the zenith angles at the two boundary locations of the sky sector, Div_{azi} being the number of azimuthal divisions of a sky atlas, W(θ, α) being the ratio of a sky sector diffuse radiation amount to a total sector diffuse radiation amount, t_{c} being a duration, and τ_{b} being the atmospheric transmittance in the shortest path.

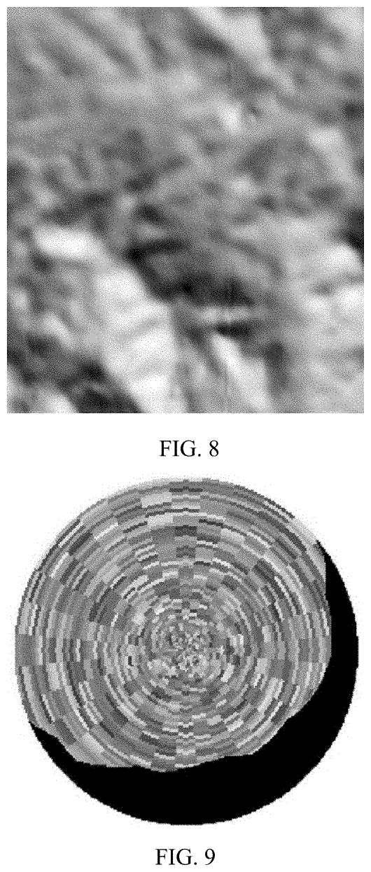

In order to calculate the diffuse radiation at the observation point, a hemispherical view representing the entire sky needs to be created, and be divided into a series of sectors according to the zenith angle and the azimuth angle. It can be considered that the diffuse radiation within each sector is the same. The diffuse radiation of each sector is calculated according to the respective direction, and is superimposed with the hemispherical viewshed to acquire the diffuse radiation distribution at the observation point, so that the total diffuse solar radiation amount received by the observation point can be acquired. The hemispherical view of the sky is defined according to 36 zenith divisions (a division angle of 10°) and 50 azimuth divisions, and in conjunction with the hemispherical viewshed, the distribution of the diffuse solar radiation received by the observation point can be acquired, as shown in FIG. 9.

Similarly, the diffuse solar radiation received in each location in the Tanyugou tunnel area was calculated, and the distribution of the diffuse solar radiation energy received by the earth surface in this area was acquired, as shown in FIG. 10.

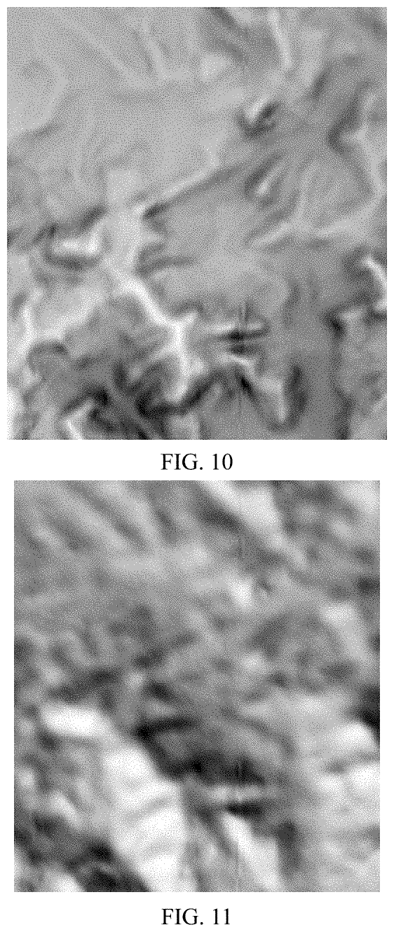

The sum of the direct solar radiation energy and the diffuse solar radiation energy received by the earth surface was acquired, and the distribution of the total solar radiation energy received by the earth surface in the Tanyugou tunnel area was acquired, as shown in FIG. 11.

(3) Hyperspectral image-based emulation and construction of mountain mass background heat propagation model

For the actual earth surface having the soil-vegetation mixture, the components are distributed alternately, and energy is transmitted between the components and the atmosphere, with energy balancing processes thereof being coupled to each other.

According to the energy conservation law, the energy and heat balance equation of the natural earth surface can be expressed as follows:

αEₛᵤₙ+εE_{sky}−G−M−LE−H=0

α representing a short-wave infrared absorption rate of the earth surface, Eₛᵤₙ representing solar irradiance received by the earth surface, ϵ representing long-wave infrared emissivity of the earth surface, E_{sky} representing atmospheric irradiance received by the earth surface, and G, M, LE, and H respectively representing downward thermal conduction flux of the earth surface, radiant exitance of the earth surface, and latent and sensible heat exchange flux.

In meteorology, the soil-vegetation-atmosphere transfer model is broadly defined as a physics-chemistry-biology combined model in which the important role of the vegetation in the process of energy and material transfer between interfaces in a soil-vegetation-atmosphere transfer system is considered in the land surface process, and the model is effectively used to investigate the atmosphere, vegetation, earth surface, soil, and water in the underlying water layer in a soil-vegetation-atmosphere system and the interaction and relevant relationships therebetween.

A soil-vegetation mixed earth surface infrared radiation temperature field coupling solving model was proposed in accordance with the principle of the SVAT model, and the model was used to calculate emulated earth surface temperature field and infrared radiation field. With reference to the principle of the model, the following assumptions can be made:

<1> Over a short time interval, the temperature change caused by the exchange and transfer of energy between the earth surface and the environment is very small, and it can be determined that the earth surface temperature field is in a steady state.

<2> The internal energy change, which is physiologically caused in the plant, over a short time is ignored.

<3> To simplify the calculation, only the energy exchange between the soil and the vegetation canopy in the vertical direction is taken into account.

<4> Latent and sensible heat exchange indirectly caused between the soil and the vegetation canopy is not taken into account.

Heat balance equations are respectively established for the soil and the vegetation:

VegF·R_{nc}=H_{ca}+H_{cg}+LE_{ca}+LE_{cg}+G_{c}

(1−VegF)·R_{ng}=H_{ga}+H_{gc}+LE_{ga}+LE_{gc}+G_{g}

VegF being a vegetation cover ratio, R_{nc} being net radiation of the vegetation canopy, R_{ng} being net radiation of the soil, H, LE, and G respectively representing sensible heat exchange, latent heat exchange, and downward thermal conduction flux, subscripts a, c, and g respectively representing air, vegetation, and earth surface, H_{ca} being energy of sensible heat exchange between the vegetation and the air, H_{dg} being energy of sensible heat exchange between the vegetation and the earth surface, LE_{ca} being energy of latent heat exchange between the vegetation and the air, LE_{cg} being energy of latent heat exchange between the vegetation and the earth surface, G_{c} being downward thermal conduction flux of the vegetation, H_{ga} being energy of sensible heat exchange between the earth surface and the air, H_{gc} being energy of sensible heat exchange between the earth surface and the vegetation, LE_{ga} being energy of latent heat exchange between the earth surface and the air, LE_{gc} being energy of latent heat exchange between the earth surface and the vegetation, and G_{g} being downward thermal conduction flux of the earth surface.

$${R}_{nc} = {Q}_{cdsun} + {Q}_{cdsky} + {Q}_{crsun} + {Q}_{crsky} - 2 {η}_{l} {M}_{c} + {η}_{l} {ε}_{c} {M}_{g} \\ {R}_{ng} = {Q}_{gsun} + {Q}_{gsky} + {η}_{l} {ε}_{g} {M}_{c} - {M}_{g} \\ {G}_{c} = \{ \begin{matrix}0.1 {R}_{nc} , & within sunshine hours \\ - 0.5 {R}_{nc} , & sunset\end{matrix} \\ {G}_{g} \approx {k}_{l} ( {T}_{g} - {T}_{0} ) / ξ {z}_{0}$$

R_{nc} being net radiation of the vegetation canopy, R_{ng} being net radiation of the soil, Q_{cdsun} being the direct solar radiation energy received by the vegetation canopy, Q_{cdsky} being direct atmospheric radiation energy received by the vegetation canopy, Q_{crsun} being soil reflected solar radiation energy absorbed by the vegetation canopy, Q_{crsky} being soil reflected atmospheric radiation energy absorbed by the vegetation canopy, ηₗ being efficiency of energy transfer from the vegetation canopy to the soil, M_{c} being thermal radiation energy absorbed by the vegetation canopy, ηₗϵ_{c} being the efficiency of energy transfer from the soil to the vegetation canopy, M_{g} being thermal radiation energy absorbed by the soil, Q_{gsun} being solar radiation energy absorbed by the soil, Q_{gsky} being atmospheric radiation energy absorbed by the soil, kₗ representing the thermal conductivity of the surface layer of the soil, T_{g} representing radiation temperature of the surface layer of the soil, T₀ representing the temperature at a certain depth below the surface layer of the soil, and ξz₀ being the thickness of the surface layer of the soil.

In the process in which the solar radiation and the atmospheric radiation pass through the vegetation canopy and reach the surface layer of the soil, it can be seen, according to the Lambert-Beer law, that the radiation amount attenuates due to the blocking performed by the leaves of vegetation, and the degree of attenuation is typically described by using an extinction coefficient. For an evenly distributed vegetation population, the extinction coefficient of the vegetation canopy with respect to solar radiation and atmospheric radiation may respectively be 0.4 and 0.8. A method for calculating transmittance of canopy with respect to the solar radiation and the atmospheric radiation is:

ηₛ=1−exp(−0.4LAI)

ηₗ=1−exp(−0.8LAI)

where LAI is a leaf area index. The leaf area index is calculated by using a random number generation method, so that the ultimately acquired infrared radiation of earth surface vegetation has an extremely large error.

Given the problem of the difficulty in actual sampling and estimation precision of the leaf area index, the leaf area index is estimated by using a normalized difference vegetation index (NDVI): first, preprocessing an acquired multispectral image; then, using reflectance of the visible red light and near-infrared bands of the multispectral image to calculate the normalized difference vegetation index according to the following formula; and finally, using a non-linear model to estimate the leaf area index:

$$NDVI = \frac{{ρ}_{NIR} - {ρ}_{R}}{{ρ}_{NIR} + {ρ}_{R}}$$

where ρ_{NIR} and ρ_{R} respectively represent reflectance of the near-infrared and red bands of the multispectral image.

The direct solar radiation and atmospheric radiation absorbed by the canopy and the solar radiation and atmospheric radiation absorbed by the canopy and reflected by the soil are calculated as in the following formulas:

Q_{cdsun}=(ηₛ−α_{c})Qₛᵤₙ

Q_{cdsky}=ηₗε_{c}Q_{sky}

Q_{crsun}=(1−ηₛ)α_{g}Qₛᵤₙ

Q_{crsky}=(1−ε_{g})(1−ηₗ)ε_{c}Q_{sky}

α_{c} and ε_{c} being respectively absorptivity and emissivity of the vegetation canopy, α_{g} and ε_{g} being respectively absorptivity and emissivity of the surface layer of the soil, Qₛᵤₙ being solar radiation reaching the vegetation canopy, and Q_{sky} being atmospheric radiation reaching the vegetation canopy;

M_{c}=ε_{c}σT_{c}⁴

M_{g}=ε_{g}σT_{g}⁴

σ being the Stefan-Boltzmann constant, T_{c} being the vegetation canopy radiation temperature to be calculated, and T_{g} being radiation temperature of the surface layer of the soil.

Calculation of the amount of latent heat exchange and the amount of sensible heat exchange between the vegetation canopy and soil and air is as follows:

$${LE}_{ca} = \frac{Δ ( {R}_{nc} - {G}_{c} ) + {ρ}_{a} {c}_{p} \frac{{e}_{s} - {e}_{a}}{{R}_{a}}}{Δ + γ ( 1 + \frac{{R}_{s}}{{R}_{a}} )} \\ {LE}_{gc} = VegF \cdot \frac{{ρ}_{a} {c}_{p}}{γ ( {R}_{a} + {R}_{s} )} \cdot ( {k}_{d} ( {T}_{g} - {T}_{c} ) + {D}_{a} ) \\ {LE}_{ga} = ( 1 - VegF ) \cdot \frac{{ρ}_{a} {c}_{p}}{γ ( {R}_{a} + {R}_{s} )} \cdot ( {k}_{d} ( {T}_{g} - {T}_{a} ) + {D}_{a} ) \\ {H}_{ca} = {ρ}_{a} {c}_{p} \frac{{T}_{c} - {T}_{a}}{{R}_{a}} \\ {H}_{ga} = ( 1 - VegF ) \cdot {ρ}_{a} {c}_{p} \frac{{T}_{g} - {T}_{a}}{{R}_{a}} \\ {H}_{gc} = VegF \cdot {ρ}_{a} {c}_{p} \frac{{T}_{g} - {T}_{c}}{{R}_{a}}$$

ρₐ being air density, cₚ being a specific heat capacity of air at constant pressure, γ being a psychrometer constant, k_{d} and Dₐ being respectively saturation specific humidity and air specific humidity difference at the air temperature of Tₐ, Rₐ and Rₛ being respectively boundary layer resistance and stomatal resistance of a vegetation population, the values of the above parameters being acquired according to relevant meteorological data and formulas, eₛ being solar irradiance, and eₐ being air irradiance.

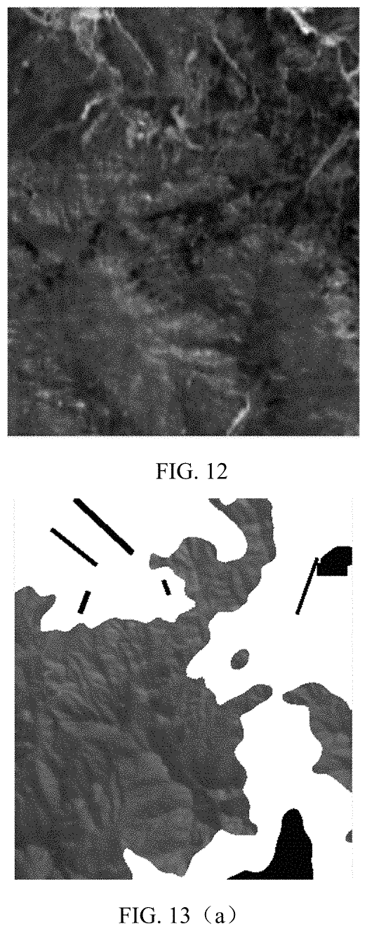

The system of soil and vegetation canopy heat balance equations was formed and calculated to acquire mixed earth surface temperature field distribution, and then mixed earth surface infrared radiation energy distribution was acquired by using the radiation formula, as shown in FIG. 12.

(4) Inverted detection and positioning of subterranean target

By performing analysis and calculation on the mountain mass background heat propagation model and the total solar radiation energy distribution model, an image of emulated infrared radiation emitted by the vegetation on the mountain mass surface and an image of distribution of total solar radiation energy received by the mountain mass surface can be acquired. Practically, when being transmitted, disturbance caused by a target is subjected to a distortion effect of a mountain mass medium, and thermal disturbance thereof has been subjected to the distortion effect of the medium. This distorted disturbance field is superimposed on the mountain mass background heat flow field (output of the model of thermal radiation between the mountain mass and the air layer constructed by means of the along-tunnel thermal energy radiation model in conjunction with the mountain mass background heat propagation model and the total solar radiation energy distribution model is the mountain mass background heat flow field), thereby forming the observed infrared radiation disturbance image. During investigation of the disturbance of the strip-like subterranean tunnel in the mountain mass, the interference from the mountain mass background heat flow field needs to be filtered out, and the distortion process needs to be reversed, so as to acquire actual distribution of the disturbance of the target.

As the heat in the mountain mass is conducted in the rock formation, a directional heat flow is generated. Similar to the penetration of X-rays, the heat flow at the bottom of the mountain mass can “penetrate” the rock formation to reach the mountain mass surface, thereby forming a vector heat flow field. Due to different geological conditions, the heat flow transmitting in different rock formations is subjected to different levels of attenuation. In addition, a certain relationship is present between the heat flow field and the internal temperature field of the mountain mass, and may be substantially a linear relationship. The infrared radiation of the mountain mass surface acquired from an infrared remote sensing image can be considered to be a combination of all layers of heat flow field of the mountain mass.

Ideally, the heat flux per unit area is as follows:

$$HF = {c}_{m} k \frac{\partial T}{\partial h}$$

cₘ being a volumetric heat capacity of a rock formation medium, k being thermal conductivity of the rock formation medium, and

$$\frac{\partial T}{\partial h}$$

being a vertical temperature gradient, which can be calculated by means of difference approximation, where the temperature gradient needs to be calculated by using the temperature field, and it can be seen that the temperature gradient and the temperature field have a substantially linear relationship therebetween.

The formation temperature field distribution at the same elevation is substantially the same. Similarly, according to the distribution of the rock formation, it can be considered that the heat flow field is also the same. Each layer of heat flow field energy is calculated, and the mountain mass heat flow field energy of different thicknesses is sequentially filtered out by using the actual infrared radiation of the mountain mass acquired by means of the infrared remote sensing image, thereby effectively protecting target information, and acquiring target disturbance signal distribution that is relatively more accurate.

Because the pattern of heat transfer of the strip-like subterranean tunnel in the mountain mass is in accordance with a mathematical model of thermal conduction, the mountain mass and target temperature field distribution can be acquired according to the heat transfer theorem and pattern, and then the heat flow field distribution being a combination of the mountain mass and target temperature field distribution can be calculated. Since the model of thermal radiation between the mountain mass and the air layer is a three-dimensional structure, the formula of distribution of the energy field also needs to be expressed in a three-dimensional form. It is assumed that the radiation energy at (x₀, y₀, z₀) on the mountain mass surface at a certain time t₀ is BT (x₀, y₀, z₀). According to the energy conservation law, the value of the radiation energy can be calculated according to heat flow field energy of the subterranean strip-like target, mountain mass background heat flow field energy, radiation energy exchanged between the subterranean strip-like target and the environment and between the mountain mass and the environment, and the received solar radiation energy:

BT(x₀,y₀,z₀,t₀)=B(x,y,z,t)+T(x,y,z,t)+δ(x,y,z,t)+S(x,y,z,t)−y,z,t)

BT(x₀, y₀, z₀, t₀) being mountain mass surface radiation energy, B(x, y, z, t) being mountain mass background heat flow field energy, T(x, y, z, t) being heat flow field energy of the strip-like target, δ(x, y, z, t) being radiation energy of a contact surface between the mountain mass and air, S(x, y, z, t) being solar radiation energy received by the mountain mass surface, and Bₘ(x, y, z, t) being heat flow field energy of a rock mass in a position corresponding to the strip-like target.

In a real-life environment, the radiation energy of a contact surface between the mountain mass and air is very small, and is substantially negligible compared with the heat flow field energy of the mountain mass and the target. In the present invention, only the relationship between the mountain mass background heat flow field energy, the strip-like target heat flow field energy, and the received solar radiation energy is considered.

It can be seen, from the above formulas, that the heat flow field energy generated by the strip-like subterranean tunnel in the mountain mass, the mountain mass background heat flow field energy, and the solar radiation energy combine to form the observable mountain mass infrared radiation energy distribution. By transforming the above formula, a calculation formula of strip-like target heat flow field energy can be acquired, and is as follows:

T(x,y,z,t)=BT(x,y,z,t)+Bₘ(x,y,z,t)—B(x,y,z,t)−S(x,y,z,t)

In a detection inversion positioning process, energy contained in mountain mass backgrounds of different thicknesses needs to be calculated with reference to mountain mass background heat flow field energy distribution, specifically as follows:

E(x,y,t)=∫_{z1(x,y)}^{z2(x,y)}HF(x,y,z,t)·A(z)·ε(z)dz

A(z) and ε(z) being respectively a cross-sectional area and a heat flow attenuation coefficient at a certain elevation in the mountain mass, z1(x, y) and z2(x, y) being respectively mountain mass surface elevation coordinates and elevation coordinates at a certain depth below the surface, and z2(x, y) being adjusted to calculate the heat flow field energy contained in the mountain mass backgrounds of different thicknesses.

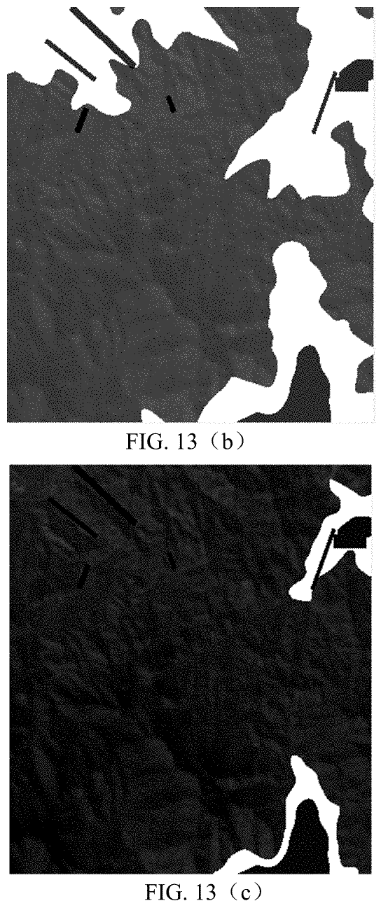

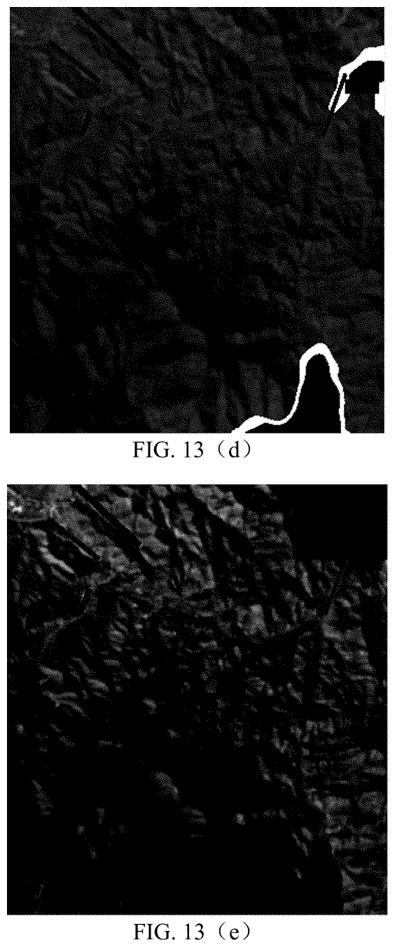

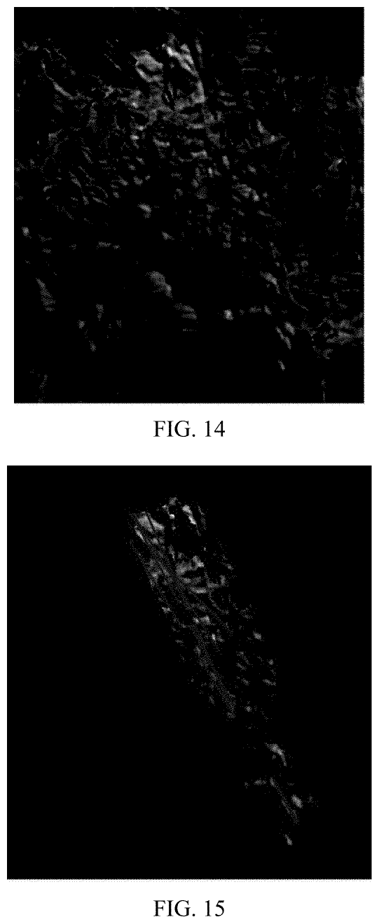

The highest elevation of the mountain mass, in which the Tanyugou tunnel is located, is 1127 m. In order to achieve a better observation effect, inverted detection and positioning was started from the elevation of 730 m, and division was performed at a vertical interval of 20 m, so as to remove background energy layer by layer in a downward direction. Layering was performed downwards continuously to acquire the disturbance signal distribution of the strip-like subterranean tunnel in the mountain mass from which the mountain mass background heat flow field energy at the depths of 20 m, 40 m, 60 m, etc. had been filtered out, as shown in FIG. 13(a), FIG. 13(b), FIG. 13(c), FIG. 13(d), and FIG. 13(e).

A method for inverting an optimal elevation of a subterranean tunnel is:

a. calculating a mountain mass total radiation amount error according to an actual total radiation amount of the earth surface of the mountain mass and a total radiation amount on the infrared remote sensing image;

$$J ( a ) = {\sum }_{i = 1}^{n} {[ {Ec}_{i} - {Et}_{i} ]}^{2} \leq ε$$

ε representing an error range, and being a very small positive number, Ecᵢ representing background heat flow field energy of the mountain mass at an elevation aₖ corresponding to the i-th pixel point, and Etᵢ representing use of a total radiation amount of the i-th pixel point on the infrared remote sensing image, wherein during imaging performed by means of infrared remote sensing, interference from a sensor and an external environment incurs an error to a measured actual earth surface radiation amount, so that the mountain mass surface radiation amount acquired on the basis of the infrared remote sensing image is a combination of the actual earth surface radiation amount and an error item, as shown by the equation:

Etᵢ=Emᵢ+σ

Emᵢ representing the actual total radiation amount of the earth surface of the mountain mass of the i-th pixel point, and σ representing a measurement error item,

wherein when the measurement error is taken into account, a condition of convergence may be expressed as:

$$J ( a ) = {\sum }_{i = 1}^{n} {[ {Ec}_{i} - {Et}_{i} ]}^{2} \leq n {σ}^{2}$$

b. using an elevation aₖ of the tunnel as a variable to be inverted, setting an initial value of k to 1, and initializing a₁;

c. subtracting, from a total radiation amount of each pixel point on the current infrared remote sensing image, background heat flow field energy of the mountain mass at the elevation aₖ corresponding to the each pixel point and calculating a quadratic sum to acquire strip-like subterranean tunnel heat flow field energy of the mountain mass at the elevation aₖ;

$$J ( {a}_{k} ) = {\sum }_{i = 1}^{n} {[ {Ec}_{ik} - {Et}_{ik} ]}^{2}$$

aₖ and n respectively representing the tunnel elevation and the number of pixel points in a calculation region, Ecᵢ representing background heat flow field energy of the mountain mass corresponding to the i-th pixel point at the elevation aₖ, and Etᵢ representing use of a total radiation amount of the i-th pixel point on the infrared remote sensing image;

d. using the elevation aₖ of the tunnel of a current iteration and a search step and a search direction of the current iteration to determine an elevation aₖ₊₁ of a next iteration, wherein the search direction of the current iteration is calculated by using a search direction of a previous iteration, the strip-like subterranean tunnel heat flow field energy of the mountain mass at the elevation aₖ, and a conjugate parameter;

aₖ₊₁=aₖ+λₖdₖ

aₖ representing the k-th calculated value of the tunnel elevation a, λₖ representing the search step, and dₖ representing the search direction;

dₖ=∇J(aₖ)+βₖdₖ₋₁

where ∇J(aₖ) represents the gradient of the strip-like subterranean tunnel heat flow field energy of the mountain mass at the elevation aₖ, and may be calculated by means of central difference approximation, and βₖ represents the conjugate parameter;

e. using the elevation aₖ₊₁ of the next iteration as the elevation of the current iteration and returning to step c until the strip-like subterranean tunnel heat flow field energy of the mountain mass at the elevation aₖ is equal to the mountain mass total radiation amount error, and ending the iteration; and

f. constructing the disturbance signal distribution image according to the strip-like subterranean tunnel heat flow field energy in the mountain mass in each iteration, and using the elevation aₖ as the optimal elevation of the strip-like subterranean tunnel in the mountain mass.

In the detection inversion positioning process, when the removal of the background energy reached the burial depth of 180 m, the disturbance of the tunnel had been substantially completely acquired, and when the removal of the background energy reached 200 m, it could be seen that the change in the disturbance image was extremely small. Compared with the detection inversion positioning result of the previous height layer, almost nothing had changed in the range of the disturbance region. At this point, the added portion was mainly the interference in the region within the height layer of 180 m to 200 m. The above test proved that such interference would be progressively mitigated in the layer-by-layer detection inversion positioning process. The interference, such as rock and houses, on the mountain mass surface was further filtered out according to a visible light image. In addition, the DEM model used to calculate the solar radiation energy received by the earth surface was deviated with respect to the actual geographic location, so that some points with negative values were present in the target region, and were kept. The negative value was replaced with the most recent positive value of the point in the detection inversion positioning process. Finally, the detection inversion positioning result of the Tanyugou tunnel area was acquired, as shown in FIG. 14.

The region in which the disturbance signals were relatively more continuous and concentrated was selected from the detection inversion positioning resultant image. The Hough transform straight line detection method was used to detect any possible tunnel segment, and the discontinuous disturbance signals of the strip-like subterranean tunnel in the mountain mass were processed. The result is shown in FIG. 15.

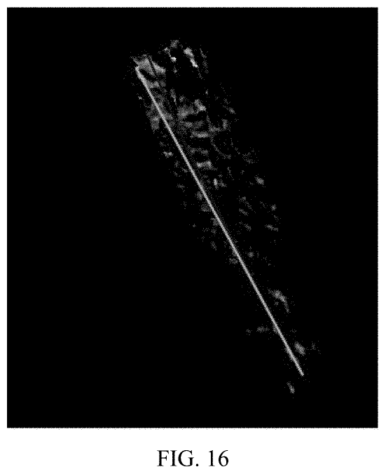

As can be seen from the resultant image, multiple straight lines were detected due to the effect of the distribution range of the disturbance points, and the most consistent straight lines were selected therefrom, and were connected. In the intermediate region in which the disturbance signal was not obvious due to the effect of the terrain, the selected line segments were connected end to end for approximate representation. Comparison between the final detection result and the actual position of the tunnel is shown in FIG. 16.

In the present invention, accurate burial depth and position information of a subterranean strip-like target can be acquired from an infrared remote sensing image by means of the method for inverted detection and positioning. Without the present invention, due to the strong interference factor of the environment and weakness of a target signal, it is difficult to perform inverted detection and positioning of a strip-like target. By means of the present invention, inverted detection of a strip-like subterranean tunnel in a mountain mass in a mountain environment can be performed.

The present invention has the following advantages as compared to the prior art:

In the present invention, the model of thermal radiation between a mountain mass and an air layer is used in conjunction with DEM data to calculate mountain mass surface solar radiation energy, and iteratively calculate each layer of mountain mass background heat flow field of the mountain mass and tunnel and mountain mass background heat propagation energy. The effects of the external environment on the mountain mass, such as disturbances and discrepancies in infrared data caused by vegetation on the earth surface, solar radiation, and terrain factors, are fully taken into account. The present invention solves the problem in which inverted detection and positioning cannot be effectively performed on a strip-like subterranean tunnel in a mountain mass because signals thereof in an infrared image are weakened after being conducted and modulated in a stratum. The invention thus achieves inverted detection and positioning of a tunnel in a mountain environment.

The present invention takes into account mountain mass surface solar radiation energy, and fully takes into account the effect of direct solar radiation and diffuse solar radiation in each DEM data grid. Compared with the method of using a multi-temporal infrared image to analyze a pattern of change in a target signal with time and establishing a mathematical model to calculate the position of a tunnel, the present invention more precisely takes into account effects of the external environment (direct solar radiation, diffuse radiation, vegetation on the earth surface, etc.) on disturbance of energy of a strip-like subterranean tunnel in a mountain mass, such that a detection inversion result is more precise. Compared with requirements on multi-temporal infrared data in a target region, the present method acquires data more easily. Compared with the method of performing statistical analysis on infrared images of a mountainous region, identifying a signature pattern of formation of a mountain mass having a subterranean tunnel and a nearby mountain mass having no subterranean tunnel, and identifying the signature pattern by traversing, in a certain direction, an infrared image of a mountain environment in which a tunnel may be contained, so as to detect and locate a tunnel target, the present invention does not require a selection of a large number of sample segments to determine whether a tunnel is present in a mountain mass, so that the present method has higher efficiency. Multi-source information fusion is used to filter out environmental interference, so that the precision and accuracy of inverted detection and positioning of a strip-like subterranean tunnel in a mountain mass are very high.

Those skilled in the art could easily understand that the foregoing description is only preferred embodiments of the present invention and is not intended to limit the present invention. All the modifications, identical replacements and improvements within the spirit and principle of the present invention should be in the scope of protection of the present invention.

1. A method for inverted detection and positioning of a strip-like subterranean tunnel in a mountain mass, comprising the steps of:
(1) using a model of thermal radiation between the mountain mass and an air layer in conjunction with DEM data to calculate mountain mass surface solar radiation energy, and iteratively calculate each layer of background heat flow field energy of the mountain mass; and calculating mountain mass background heat propagation energy with reference to hyperspectral data;
(2) filtering out the mountain mass surface solar radiation energy and the mountain mass background heat propagation energy in an infrared remote sensing image;
(3) on the basis of step (2), using a subterranean target inversion model to filter out each layer of background heat flow field energy of the mountain mass in the infrared remote sensing image, and acquiring an optimal elevation of the strip-like subterranean tunnel in the mountain mass and a disturbance signal distribution image constructed via strip-like subterranean tunnel heat flow field energy in each layer of the mountain mass; and
(4) using a Hough transform detection method to detect a straight line in the disturbance signal distribution image, processing a strip-like discontinuous disturbance signal pattern according to the principle of relevance of tunnel engineering design, and performing fitting to acquire the orientation and topography of the tunnel;
wherein the model of thermal radiation between the mountain mass and the air layer comprises an along-tunnel thermal energy radiation model, a total solar radiation energy distribution model, and a mountain mass background heat propagation model;
the along-tunnel thermal energy radiation model is constructed by using COMSOL finite element emulation software in conjunction with DEM data and a meteorological parameter, and is used for calculating along-tunnel thermal energy radiation distribution;
the total solar radiation energy distribution model is used for calculating the mountain mass surface solar radiation energy by using a hemispherical viewshed method in conjunction with the DEM data and geographic location information of the mountain mass and the tunnel;
the mountain mass background heat propagation model is used for calculating earth surface vegetation infrared radiation distribution according to a SVAT model in conjunction with the hyperspectral data.

2. The method for inverted detection and positioning of the strip-like subterranean tunnel in the mountain mass according to claim 1, wherein a method for constructing the along-tunnel thermal energy radiation model comprises:
constructing the same on the basis of the DEM data and by using the COMSOL finite element emulation software and an energy conservation equation in a mountain mass-tunnel coupling model heat transfer process in conjunction with a tunnel surface boundary condition, thermal balance present on a contact surface between an outer surface of the tunnel and a rock formation of the mountain mass, and heat conduction flux into which a shape factor is introduced.

3. The method for inverted detection and positioning of the strip-like subterranean tunnel in the mountain mass according to claim 1, wherein a method for calculating the mountain mass surface solar radiation energy comprises the steps of:
calculating a hemispherical viewshed according to each grid of the DEM data;
combining the hemispherical viewshed, the position of the sun, and sky information, and acquiring direct solar radiation distribution and diffuse solar radiation distribution at the grid according to a direct solar radiation amount and a diffuse solar radiation amount at the grid;
superimposing the direct solar radiation distribution and the diffuse solar radiation distribution at the grid to acquire a total amount of solar radiation received by the earth surface at the grid; and
adding the total amounts of solar radiation received by the earth surface at all of the grids to acquire the mountain mass surface solar radiation energy.

4. The method for inverted detection and positioning of the strip-like subterranean tunnel in the mountain mass according to claim 3, wherein step (3) specifically comprises the steps of:
a. calculating a mountain mass total radiation amount error according to an actual total radiation amount of the earth surface of the mountain mass and a total radiation amount on the infrared remote sensing image;
b. using an elevation aₖ of the tunnel as a variable to be inverted, setting an initial value of k to 1, and initializing a₁;
c. subtracting, from a total radiation amount of each pixel point on the current infrared remote sensing image, background heat flow field energy of the mountain mass at the elevation aₖ corresponding to the each pixel point and then calculating a quadratic sum to acquire strip-like subterranean tunnel heat flow field energy of the mountain mass at the elevation aₖ;
d. using the elevation aₖ of the tunnel of a current iteration and a search step and a search direction of the current iteration to determine an elevation aₖ₊₁ of a next iteration, wherein the search direction of the current iteration is calculated by using a search direction of a previous iteration, the strip-like subterranean tunnel heat flow field energy of the mountain mass at the elevation aₖ, and a conjugate parameter;
e. using the elevation aₖ₊₁ of the next iteration as the elevation of the current iteration and returning to step c until the strip-like subterranean tunnel heat flow field energy of the mountain mass at the elevation aₖ is equal to the mountain mass total radiation amount error, and ending the iteration; and
f. constructing the disturbance signal distribution image according to the strip-like subterranean tunnel heat flow field energy in the mountain mass in each iteration, and using the elevation aₖ as the optimal elevation of the strip-like subterranean tunnel in the mountain mass.

5. The method for inverted detection and positioning of the strip-like subterranean tunnel in the mountain mass according to claim 3, wherein a method for calculating the direct solar radiation amount E_{dir} is:
E_{dir}=ΣE_{dir}(θ,α)
E_{dir}(θ,α)=S_{const}*τ_{b}^{m(θ)}*SD_{θ,α}*SunG_{θ,α} cos(AngI(θ,α))
m(θ)=^{-0.000118*h-1.638*10}^{^{−9}}^{*h}^{²}/cos(θ)
AngI(θ,α)=arc cos(cos(θ)*cos(G_{z})+sin(θ)*sin(G_{z})*cos(α−G_{α}))
S_{const} being a solar constant, τ_{b} being atmospheric transmittance in a shortest path, m(θ) being an optical path length, SD_{θ,α} being a duration, SunG_{θ,α} being a porosity of a solar atlas sector, AngI(θ,α) being an angle of incidence of a sky sector centroid relative to a mountain mass surface perpendicular line, G_{z} and G_{α} being respectively a zenith angle and an azimuth angle of the mountain mass surface, θ₁ and θ₂ being respectively zenith angles at two boundary locations of a sky sector, and h being an elevation value;
a method for calculating the diffuse solar radiation amount E_{dif} is:
E_{dif}=ΣE_{dif}(θ,α)
E_{dif}(θ,α)=E_{glb}*p*t_{c}*SkyG_{θ,α}W(θ,α)*cos(AngI(θ,α))
E_{glb}=(S_{const}τ(τ_{b}^{m(θ)})/(1−p)
W(θ,α)=(cos θ₂−cos θ₁)/Div_{azi}
S_{const} being the solar constant, AngI(θ, α) being the angle of incidence of the sky sector centroid relative to the surface perpendicular line, E_{glb} being a normal total radiation amount, p being a ratio of diffuse radiation flux, SkyG_{θ, α} being a porosity of the sky sector, h being an elevation value, θ₁ and θ₂ being respectively the zenith angles at the two boundary locations of the sky sector, Div_{azi} being the number of azimuthal divisions of a sky atlas, W(θ, α) being the ratio of a sky sector diffuse radiation amount to a total sector diffuse radiation amount, t_{c} being a duration of diffuse solar radiation, τ_{b} being the atmospheric transmittance in the shortest path, and E_{dir}(θ, α) and E_{dif}(θ, α) being respectively direct radiation energy and diffuse radiation energy at a centroid where an observation point is located, with a zenith angle being θ and an azimuth angle being α.

6. A system for inverted detection and positioning of a strip-like subterranean tunnel in a mountain mass, comprising:
a mountain mass background heat flow field calculation module, using a model of thermal radiation between the mountain mass and an air layer in conjunction with DEM data to calculate mountain mass surface solar radiation energy, and iteratively calculate each layer of background heat flow field energy of the mountain mass; and calculating mountain mass background heat propagation energy with reference to hyperspectral data;
a disturbance signal distribution image construction module, used for filtering out the mountain mass surface solar radiation energy and the mountain mass background heat propagation energy in an infrared remote sensing image; and then using a subterranean target inversion model to filter out each layer of background heat flow field energy of the mountain mass in the infrared remote sensing image, and acquiring an optimal elevation of the strip-like subterranean tunnel in the mountain mass and a disturbance signal distribution image constructed via strip-like subterranean tunnel heat flow field energy in each layer of the mountain mass; and
a target detection location fitting module, using a Hough transform detection method to detect a straight line in the disturbance signal distribution image, processing a discontinuous disturbance signal of the strip-like subterranean tunnel in the mountain mass according to the principle of relevance of tunnel engineering design, and performing fitting to acquire the orientation and topography of the tunnel;
wherein the mountain mass background heat flow field calculation module comprises an along-tunnel thermal energy radiation distribution construction unit, a total solar radiation energy distribution construction unit, and a mountain mass background heat propagation distribution construction unit;
the along-tunnel thermal energy radiation distribution construction unit is used for constructing an along-tunnel thermal energy radiation model by using COMSOL finite element emulation software in conjunction with DEM data and a meteorological parameter;
the total solar radiation energy distribution construction unit is used for constructing a total solar radiation energy distribution model by using a hemispherical viewshed method in conjunction with the DEM data and geographic location information of the mountain mass and the tunnel, the total solar radiation energy distribution model being used for calculating the mountain mass surface solar radiation energy;
the mountain mass background heat propagation distribution construction unit is used for constructing a mountain mass background heat propagation model according to a SVAT model in conjunction with the hyperspectral data.

7. The system for inverted detection and positioning of the strip-like subterranean tunnel in the mountain mass according to claim 6, wherein a method for constructing the along-tunnel thermal energy radiation model comprises:
constructing the same on the basis of the DEM data and by using the COMSOL finite element emulation software and an energy conservation equation in a mountain mass-tunnel coupling model heat transfer process in conjunction with a tunnel surface boundary condition, thermal balance present on a contact surface between an outer surface of the tunnel and a rock formation of the mountain mass, and heat conduction flux into which a shape factor is introduced.

8. The system for inverted detection and positioning of the strip-like subterranean tunnel in the mountain mass according to claim 6, wherein a method for calculating the mountain mass surface solar radiation energy comprises the steps of:
calculating a hemispherical viewshed according to each grid of the DEM data;
combining the hemispherical viewshed, the position of the sun, and sky information, and acquiring direct solar radiation distribution and diffuse solar radiation distribution at the grid according to direct solar radiation energy and diffuse solar radiation energy at the grid;
superimposing the direct solar radiation distribution and the diffuse solar radiation distribution at the grid to acquire total energy of solar radiation received by the earth surface at the grid; and
adding the total energy of solar radiation received by the earth surface at all of the grids to acquire the mountain mass surface solar radiation energy.

9. The system for inverted detection and positioning of the strip-like subterranean tunnel in the mountain mass according to claim 8, wherein a method for acquiring the optimal elevation of the strip-like subterranean tunnel in the mountain mass and the interference signal distribution image specifically comprises the steps of:
a. calculating a mountain mass total radiation amount error according to an actual total radiation amount of the earth surface of the mountain mass and a total radiation amount on the infrared remote sensing image;
b. using an elevation aₖ of the tunnel as a variable to be inverted, setting an initial value of k to 1, and initializing a₁;
c. subtracting, from a total radiation amount of each pixel point on the current infrared remote sensing image, background heat flow field energy of the mountain mass at the elevation aₖ corresponding to the each pixel point and then calculating a quadratic sum to acquire strip-like subterranean tunnel heat flow field energy of the mountain mass at the elevation aₖ;
d. using the elevation aₖ of the tunnel of a current iteration and a search step and a search direction of the current iteration to determine an elevation aₖ₊₁ of a next iteration, wherein the search direction of the current iteration is calculated by using a search direction of a previous iteration, the strip-like subterranean tunnel heat flow field energy of the mountain mass at the elevation aₖ, and a conjugate parameter;
e. using the elevation aₖ₊₁ of the next iteration as the elevation of the current iteration and returning to step c until the strip-like subterranean tunnel heat flow field energy of the mountain mass at the elevation aₖ is equal to the mountain mass total radiation amount error, and ending the iteration; and
f. constructing the disturbance signal distribution image according to the strip-like subterranean tunnel heat flow field energy in the mountain mass in each iteration, and using the elevation aₖ as the optimal elevation of the strip-like subterranean tunnel in the mountain mass.

10. The system for inverted detection and positioning of the strip-like subterranean tunnel in the mountain mass according to claim 8, wherein a method for calculating the direct solar radiation amount E_{dir} is:
E_{dir}=ΣE_{dir}(θ,α)
E_{dir}(θ,α)=S_{const}*τ_{b}^{m(θ)}*SD_{θ,α}*SunG_{θ,α} cos(AngI(θ,α))
m(θ)=^{-0.000118*h-1.638*10}^{^{−9}}^{*h}^{²}/cos(θ)
AngI(θ,α)=arc cos(cos(θ)*cos(G_{z})+sin(θ)*sin(G_{z})*cos(α−G_{α}))
S_{const} being a solar constant, τ_{b} being atmospheric transmittance in a shortest path, m(θ) being an optical path length, SD_{θ,α} being a duration, SunG_{θ,α} being a porosity of a solar atlas sector, AngI(θ,α) being an angle of incidence of a sky sector centroid relative to a mountain mass surface perpendicular line, G_{z} and G_{α} being respectively a zenith angle and an azimuth angle of the mountain mass surface, θ₁ and θ₂ being respectively zenith angles at two boundary locations of a sky sector, and h being an elevation value;
a method for calculating the diffuse solar radiation amount E_{dif} is:
E_{dif}=ΣE_{dif}(θ,α)
E_{dif}(θ,α)=E_{glb}*p*t_{c}*SkyG_{θ,α}W(θ,α)*cos(AngI(θ,α))
E_{glb}=(S_{const}τ(τ_{b}^{m(θ)})/(1−p)
W(θ,α)=(cos θ₂−cos θ₁)/Div_{azi}
S_{const} being the solar constant, AngI(θ, α) being the angle of incidence of the sky sector centroid relative to the surface perpendicular line, E_{glb} being a normal total radiation amount, p being a ratio of diffuse radiation flux, SkyG_{θ, α} being a porosity of the sky sector, h being an elevation value, θ₁ and θ₂ being respectively the zenith angles at the two boundary locations of the sky sector, Div_{azi} being the number of azimuthal divisions of a sky atlas, W(θ, α) being the ratio of a sky sector diffuse radiation amount to a total sector diffuse radiation amount, t_{c} being a duration of diffuse solar radiation, τ_{b} being the atmospheric transmittance in the shortest path, and E_{dir}(θ, α) and E_{dif}(θ, α) being respectively direct radiation energy and diffuse radiation energy at a centroid where an observation point is located, with a zenith angle being θ and an azimuth angle being α.
